(19) United States
(12) Patent Application Publication
(10) Pub. No.: US 2008/0173930 A1
(43) Pub. Date: Jul. 24, 2008

(54) Semiconductor memory device and method for manufacturing the same

(76) Inventors: Hiroshi Watanabe, Yokohama-Shi (JP); Daisuke Matsushita, Hiratsuka-Shi (JP); Kouichi Muraoka, Sagamihara-Shi (JP); Yasushi Nakasaki, Yokohama-Shi (JP); Koichi Kato, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/902,132

(22) Filed: Sep. 19, 2007

(30) Foreign Application Priority Data
Jan. 24, 2007 (JP) 2007-014008

(51) Int. Cl. H01L 29/788; H01L 21/285; H01L 29/792

(52) U.S. Cl. 257/321; 257/324; 438/763; 257/E21.16; 257/E29.3; 257/E29.309

(57) ABSTRACT

The present invention provides a semiconductor memory device having a tunnel insulating film that does not degrade the endurance characteristics when writing/erasing is repeated, even if the tunnel insulating film is made thinner. The semiconductor memory device includes: a semiconductor substrate; a first insulating film formed on the semiconductor substrate, and including a silicon oxynitride film and a silicon-rich silicon oxide film formed on the silicon oxynitride film, the silicon oxynitride film having a stacked structure formed with a first silicon oxynitride layer, a silicon nitride layer, and a second silicon oxynitride layer in order; a charge storage layer formed on the first insulating film; a second insulating film formed on the charge storage layer; and a control gate formed on the second insulating film.

### CROSS-REFERENCE TO RELATED APPLICATION

This application is based upon and claims the benefit of priority from prior Japanese Patent Application No. 2007-14008 filed on Jan. 24, 2007 in Japan, the entire contents of which are incorporated herein by reference.

### BACKGROUND OF THE INVENTION

1. Field of the Invention

The present invention relates to a semiconductor memory device and a method for manufacturing the semiconductor memory device.

2. Related Art

Each memory cell in a nonvolatile semiconductor memory device such as a NAND flash memory is characterized by the floating gate that is covered with an insulating film and is made of polysilicon. By controlling the voltage (control voltage) to be applied to the control gate formed on the floating gate via an interelectrode insulating film, charges can be injected from the substrate into the floating gate via a tunnel insulating film by virtue of a FN (Fowler-Nordheim) tunneling effect (writing), or charges are pulled out from the floating gate via the tunnel insulating film (erasing). In this manner, the threshold voltage of each memory cell is changed.

Since a high electric field is applied to the tunnel insulating film when electrons are put into or pulled out from the floating gate, the tunnel insulating film is placed under high stress. As a result, defects are formed in the tunnel insulating film, and the leakage current might increase accordingly. As a tunnel insulating film in which defects are not easily formed, there has been known a three-layer structure having a silicon nitride film interposed between silicon oxide films, with the silicon nitride film having tri-coordinate nitrogen bonds (see JP-A 2006-13003 (KOKAI), for example).

As the device size is reduced so as to lower the cost per bit, the variation width in threshold voltage has to become smaller for suppressing the influence of intercell interference, and the narrowed variation hinders the miniaturization. One of the factors that make it difficult to control the variation width is the electrons tunneling through the interelectrode insulating film interposed between the floating gate and the control gate (leakage through the interelectrode insulating film). The leakage through the interelectrode insulating film is caused when electrons are injected into the floating gate from the substrate. As a result, the threshold voltage of the memory cell cannot be set at a desired value, and there are other problems than that.

By the technique disclosed in JP-A 2006-13003 (KOKAI), there might be many Si—O—H bonds existing in the surface of the silicon substrate, judging from the disclosed manufacturing method. As a result, dangling bonds are formed in the silicon-oxide on the substrate after the oxidation, as the O—H bands detach from the silicon-oxide when writing/erasing is repeated, and the threshold voltage of the memory cell varies. This causes degradation of the endurance characteristics when writing/erasing is repeated.

In each memory cell of a NAND flash memory, floating gate fringe capacity coupling (FG fringe coupling) is caused between the side faces of the floating gate and the diffusion layer of the memory cell, as shown in FIG. 35. The feature of a FG fringe lies in that the size of the FG fringe does not change after miniaturization. This contrasts with the fact that the interelectrode insulating film capacity and the tunnel insulating film capacity decrease as the device size and the facing area are reduced. Therefore, the contribution of the FG fringe becomes relatively larger as the device size becomes smaller.

The FG fringe coupling contributes to the capacitance coupling between the substrate and the floating gate. Therefore, as the proportion of the FG fringe becomes larger, the capacitance coupling between the floating gate and the control gate becomes relatively smaller, resulting in a decrease in capacitance coupling ratio. A decrease in capacitance coupling ratio leads to a decrease in the ratio of the electric field induced in the tunnel insulating film between the substrate and the floating gate with respect to the electric field induced in the interelectrode insulating film. As a result, the leakage through the interelectrode insulating film is increased.

To perform proper writing, it is necessary to induce an electric field of 10 MV/cm or higher in the tunnel insulating film, and to restrict the electric field to be applied to the interelectrode insulating film to 3 MV/cm or lower, as shown in FIG. 36. When the capacitance coupling ratio becomes lower, the field distribution relationship between the tunnel insulating film and the interelectrode insulating film is changed, resulting in a decrease of the electric field of the tunnel insulating film and an increase of the electric field of the interelectrode insulating film. This proves that the influence of the FG fringe on the capacitance coupling ratio is a critical issue.

The relationship between the FG fringe and the miniaturization is now described. The capacitance of the tunnel insulating film is proportional to the gate area, and decreases at the rate of the square of the gate length as the device size becomes smaller. This is a much higher rate than the rate at which the FG fringe coupling becomes smaller. Accordingly, the influence of the FG fringe coupling on the capacitance coupling ratio cannot be ignored in the generation of 55-nm and beyond.

Next, the factor that lowers the writing efficiency, other than the FG fringe, is described. As shown in FIG. 37, a depletion layer is formed at the interface between the floating gate and the tunnel insulating film while writing, which reduces the electric field across the tunnel insulating film and then lowers the writing efficiency.

Here, the influence of depletion layer is described. FIG. 38 illustrates a depletion layer of n⁺-poly-gate. Since a Fermi level exists in the conduction band, which is not a case with a silicon substrate, there remains a region (an incomplete depletion layer) from which electrons are not completely removed even if the band bends at the polysilicon surface. A complete depletion layer that is completely depleted exists between the incomplete depletion layer and the tunnel insulating film. In reality, however, the complete depletion layer width is extremely small, and the depletion layer of n⁺-polysilicon is dominated by the incomplete depletion layer (see H. Watanabe, IEEE TED52, 2265, 2005). The point to which attention should be paid here is that the width of the n⁺-polysilicon depletion layer is underestimated, since the depletion approximation used for regular silicon is formed on the assumption that complete depletion is formed. For this reason, the depletion layer formed while writing is also underestimated. Although decreases in electric field of the tunnel insulating film due to the depletion layer of the floating gate have been ignored in the conventional study, such decreases become critical factors that should be completely eliminated when the write margin becomes smaller as the device size becomes smaller, as illustrated in FIG. 37.

Next, the influence of the accumulation layer is described. An accumulation layer of n⁺-polysilicon has been ignored on the basis of the conventional Boltzmann approximation. This is because the donor concentration of n⁺-polysilicon is very high, and it has been considered that any small band-bending at the surface of n⁺-polysilicon exponentially accumulates charges. That is, the band hardly bends in reality. However, one of the inventors of the present invention proved that this theory was wrong in a document (H. Watanabe, et al., Ext. Abs. SSDM, 504, 2005). As shown in FIGS. 39A and 39B, the accumulation layer width of n⁺-polysilicon is small, and the exponential accumulation of electrons is prohibited by a quantum exclusion effect. Instead, the band-bending becomes much larger than expected, and the density-of-state increases in the manner of a square root function in accordance with the band-bending. Since charges are accumulated not exponentially but as a square root function, the accumulation layer at the n⁺-polysilicon surface can be called a weak accumulation layer. FIG. 40 shows that the weak accumulation layer formed at the interface between the floating gate and the interelectrode insulating film while writing lowers the tunnel barrier of the interelectrode insulating film. The lowered tunnel barrier leads to an exponential increase in leakage through the interelectrode insulating film, and to a large decrease in writing efficiency.

As described above, an incomplete depletion layer reduces the electric field of the tunnel insulating film, and the FG fringe lowers the capacitance coupling ratio. The injected current flowing through the tunnel insulating film is lowered while writing. The weak accumulation layer formed at the interface between the floating gate and the interelectrode insulating film increases the leakage through the interelectrode insulating film. Since writing is performed with the use of the difference between the injected current and the leakage through the interelectrode insulating film, the writing efficiency is greatly lowered in such a way. Therefore, decreases in writing efficiency together with size reductions are a serious problem in the NAND flash memories of the 55-nm generation and beyond.

An effective solution to solve the above problem is to reduce the film thickness of the tunnel insulating film. A thinner tunnel insulating film may appear to further lower the capacitance coupling ratio. However, with a thinner tunnel insulating film, a large increase in the injected current flowing through the tunnel insulating film is achieved, and such a large increase prevents a decrease in writing efficiency at the time of a size reduction. At the same time, however, the endurance characteristics deteriorate due to the influence of electrons trapped in the vicinity of the substrate interface at the time of erasing, as shown in FIG. 41.

Referring now to FIG. 42, the mechanism of degradation of the endurance is described. When electrons move from the floating gate to the silicon substrate through the tunnel insulating film at the time of erasing, the tunneling electrons are accelerated so as to turn into hot electrons in the vicinity of the interface between the tunnel insulating film (simply made of SiO₂, for example) and the substrate. The hot electrons break the Si—O—H bonds to leave dangling bonds there.

Conventionally, degradation of the endurance characteristics has been prevented by maintaining the film thickness of the tunnel insulating film in the neighborhood of 10 nm. However, when the capacitance coupling ratio becomes lower due to the influence of the FG fringe together with a size reduction, and the writing efficiency becomes lower, the tunnel insulating film need to be made thinner as described above.

### SUMMARY OF THE INVENTION

The present invention has been made in view of these circumstances, and an object thereof is to provide a semiconductor memory device having a tunnel insulating film that does not degrade the endurance characteristics at the time of repetitive writing/erasing, even if the tunnel insulating film is made thin, and to provide a method for manufacturing such a semiconductor memory device.

A semiconductor memory device according to a first aspect of the present invention includes: a semiconductor substrate; a first insulating film formed on the semiconductor substrate, and including a silicon oxynitride film and a silicon-rich silicon oxide film formed on the silicon oxynitride film, the silicon oxynitride film having a stacked structure formed with a first silicon oxynitride layer, a silicon nitride layer, and a second silicon oxynitride layer in order; a charge storage layer formed on the first insulating film; a second insulating film formed on the charge storage layer; and a control gate that is formed on the second insulating film.

A semiconductor memory device according to a second aspect of the present invention includes: a semiconductor substrate; a first insulating film formed on the semiconductor substrate, and including a silicon oxynitride film and a silicon oxide film formed on the silicon oxynitride film, the silicon oxynitride film having a stacked structure formed with a first silicon oxynitride layer, a silicon nitride layer and a second silicon oxynitride layer in order, a total film thickness of the silicon oxide film and the second silicon oxynitride layer being equal to or greater than a value obtained by dividing binding energy of silicon and hydroxyl by an electric field across the first insulating film while erasing it and an elementary electric charge; a charge storage layer formed on the first insulating film; a second insulating film formed on the charge storage layer; and a control gate formed on the second insulating film.

A method for manufacturing a semiconductor memory device according to a third aspect of the present invention includes: placing a semiconductor substrate into a first atmosphere, thereby forming a nitride film above a surface of the semiconductor substrate, the first atmosphere containing a first nitriding gas nitriding the surface of the semiconductor substrate and a first diluent gas not substantially reacting with the semiconductor substrate during manufacture, the ratio of the sum of the partial pressure of the first diluent gas and the partial pressure of the first nitriding gas to the partial pressure of the first nitriding gas being 5 or higher, and the total pressure of the atmosphere being 40 Torr or lower; placing the semiconductor substrate having the nitride layer formed above the surface thereof into a second atmosphere, thereby forming a first oxynitride layer between the semiconductor substrate and the nitride layer, and a second oxynitride layer on a surface of the nitride layer, the second atmosphere containing an oxidizing gas and a second diluent gas not substantially reacting with the semiconductor substrate during manufacture; and depositing an oxide film on the second oxynitride layer by CVD, thereby forming a tunnel insulating film having a stacked structure formed with the first oxynitride layer, the nitride layer, the second oxynitride layer, and the oxide film in order.

### BRIEF DESCRIPTION OF THE DRAWINGS

FIG. 1 is a cross-sectional view of a semiconductor memory device in accordance with a first embodiment;

FIGS. 2(a) and 2(b) show the energy band and the nitrogen concentration profile in a section taken in a direction perpendicular to the film plane of the semiconductor memory device of the first embodiment;

FIGS. 3A and 3B are schematic views showing the atom arrangement in the silicon oxynitride film in accordance with the first embodiment;

FIG. 4 shows the relationship between the fixed charge density and the relative Gm^{max} in the silicon oxynitride film;

FIG. 5 shows the fixed charge density in the silicon oxynitride film and the thickness of the interface oxide layer;

FIG. 6 illustrates the effects of the first embodiment;

FIG. 7 shows the nitrogen concentration profile of the silicon oxynitride film in accordance with the first embodiment;

FIGS. 8A through 15B are cross-sectional views showing the procedures for manufacturing a semiconductor memory device in accordance with a second embodiment;

FIG. 16 shows nitrogen concentration profiles in the depth direction that are different from each other due to the difference in the film forming conditions for forming a silicon oxynitride film;

FIG. 17 shows the J-V characteristics that are different due to the difference in the film forming conditions for forming a silicon oxynitride film;

FIG. 18 shows the J-V characteristics of insulating films in which silicon oxide films are formed on silicon oxynitride films that are formed under different film forming conditions from each other;

FIG. 19 shows the charge retention properties of memory cells with different SILC characteristics;

FIG. 20 shows the dependence of the threshold voltage on the stress voltage application time;

FIG. 21 is a flowchart showing the manufacturing procedures in a method for manufacturing a semiconductor memory device in accordance with a third embodiment;

FIGS. 22A through 22C are cross-sectional views illustrating the common manufacturing procedures in each method for manufacturing a semiconductor memory device in accordance with third through fifth embodiments;

FIG. 23 illustrates the effects of the third embodiment;

FIG. 24 is a flowchart showing the manufacturing procedures in a method for manufacturing a semiconductor memory device in accordance with a fourth embodiment;

FIG. 25 illustrates the effects of the fourth embodiment;

FIG. 26 is a flowchart showing the manufacturing procedures in a method for manufacturing a semiconductor memory device in accordance with a fifth embodiment;

FIGS. 27 through 28 illustrate the effects of the fifth embodiment;

FIGS. 29A through 33B are cross-sectional views illustrating the common manufacturing procedures in each method for manufacturing a semiconductor memory device in accordance with a sixth embodiment;

FIG. 34 illustrates the effects of the sixth embodiment;

FIG. 35 illustrates the influence of the FG fringe:

FIG. 36 illustrates a writing method;

FIG. 37 illustrates the influence of an incomplete depletion layer;

FIG. 38 illustrates the incomplete depletion layer;

FIGS. 39A and 39B illustrate a weak storage layer;

FIG. 40 illustrates the influence of the weak storage layer;

FIG. 41 illustrates degradation of the endurance characteristics;

FIG. 42 illustrates the mechanism of degradation of the endurance characteristics;

FIG. 43 illustrates the conditions under which dangling bonds are formed; and

FIG. 44 is a cross-sectional view of a semiconductor memory device as an embodiment of the present invention.

### DETAILED DESCRIPTION OF THE INVENTION

The following is a description of embodiments of the present invention, with reference to the accompanying drawings. The present invention is not limited to the following embodiments, and various modifications may be made to them. In each of the embodiments, a FG or MONOS memory device will be described. However, the present invention can be applied to any other memory device that requires good endurance characteristics. The present invention can also be applied to a memory circuit having those memory devices integrated therein, or a system LSI having a logic circuit or the like mounted therein together with a memory circuit, for example.

### First Embodiment

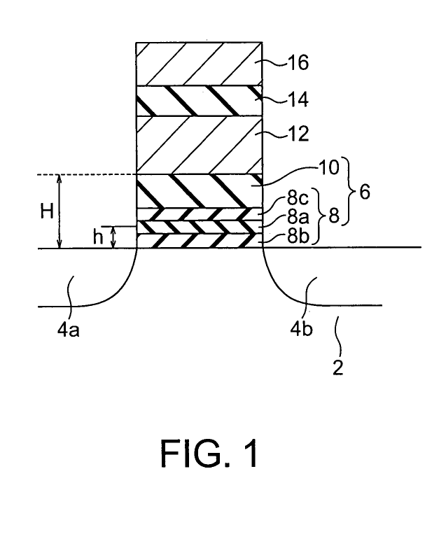

Referring now to FIG. 1, a semiconductor memory device in accordance with a first embodiment of the present invention is described. The semiconductor memory device of this embodiment includes memory cells. FIG. 1 is a cross-sectional view of one of the memory cells. The memory cell in accordance with this embodiment includes a source region 4a and a drain region 4b formed at a distance from each other on a silicon substrate 2, a tunnel insulating film 6 formed on the portion of the silicon substrate 2 located between the source region 4a and the drain region 4b, a floating gate 12 that is formed on the tunnel insulating film 6 and is made of polysilicon, an interelectrode insulating film 14 formed on the floating gate 12, and a control gate 16 formed on the interelectrode insulating film 14. The tunnel insulating film 6 includes a silicon oxynitride film 8 that is a stacked structure consisting of a silicon nitride layer 8a and silicon oxynitride layers 8b and 8c sandwiching the silicon nitride layer 8a, and a silicon oxide film 10 formed by CVD (Chemical Vapor Deposition). Being formed by CVD, the silicon oxide film 10 is a silicon-rich oxide film as it is. It is of course possible to further oxidize the silicon oxide film 10, so as to obtain a SiO₂ film or an oxygen-rich silicon oxide film. The floating gate 12 is made of polycrystalline silicon, and stores electric charges.

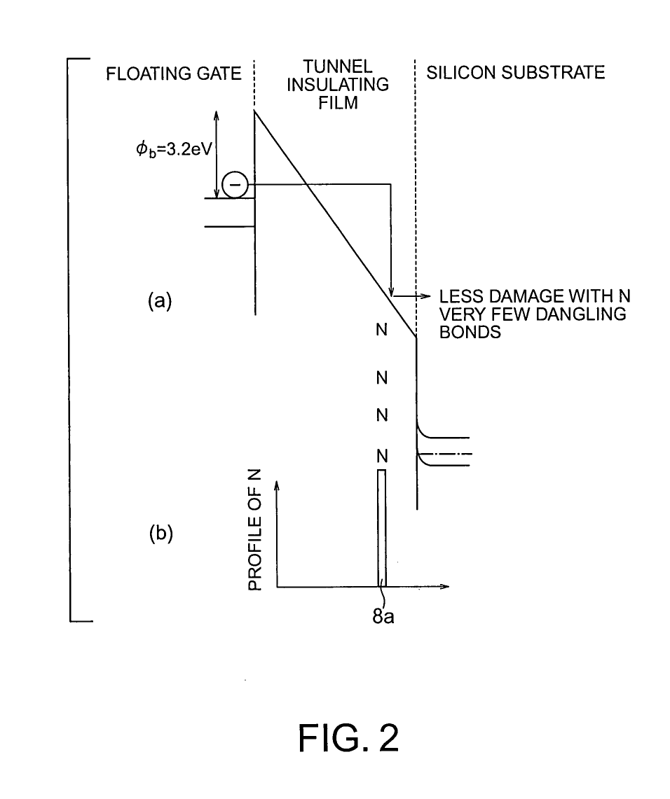

FIG. 2(a) shows the energy band in a section taken in a direction perpendicular to the film plane of the floating gate 12 and the tunnel insulating film 6. FIG. 2(b) shows the nitrogen profile of the tunnel insulating film 6.

The silicon nitride layer 8a of the tunnel insulating film 6 in accordance with this embodiment exists near the interface with the silicon substrate 2 and has a steep profile of nitrogen (N) as described in FIG. 2(b). In the silicon nitride layer 8a, Si—N bonds exist, but few Si—O—H bonds exist. Accordingly, even if writing or erasing is repeatedly performed, dangling bonds are not easily formed, and degradation of the endurance characteristics can be prevented. The silicon nitride layer 8a is approximately 0.3 nm in layer thickness, and has a nitride concentration of 55% to 57%. More specifically, the silicon nitride layer 8a is substantially a Si₃N₄ layer. The first-neighbor atoms of silicon are nitrogen atoms, and the second-neighbor atoms are silicon atoms. The nitrogen concentration in the silicon oxynitride layers 8b and 8c is restricted to 10% or lower. This is because, since strong Si—N bonds are formed in the silicon nitride layer 8a, the oxygen reacts with the surface of the silicon nitride layer 8a having the remaining dangling bonds (defects are easily formed at the surface that has a different structure from an ideal bulk structure), and with the Si substrate 2 after passing through the silicon nitride layer 8a. Accordingly, the silicon oxynitride layers 8b and 8c are substantially silicon oxide layers (SiO₂ layers).

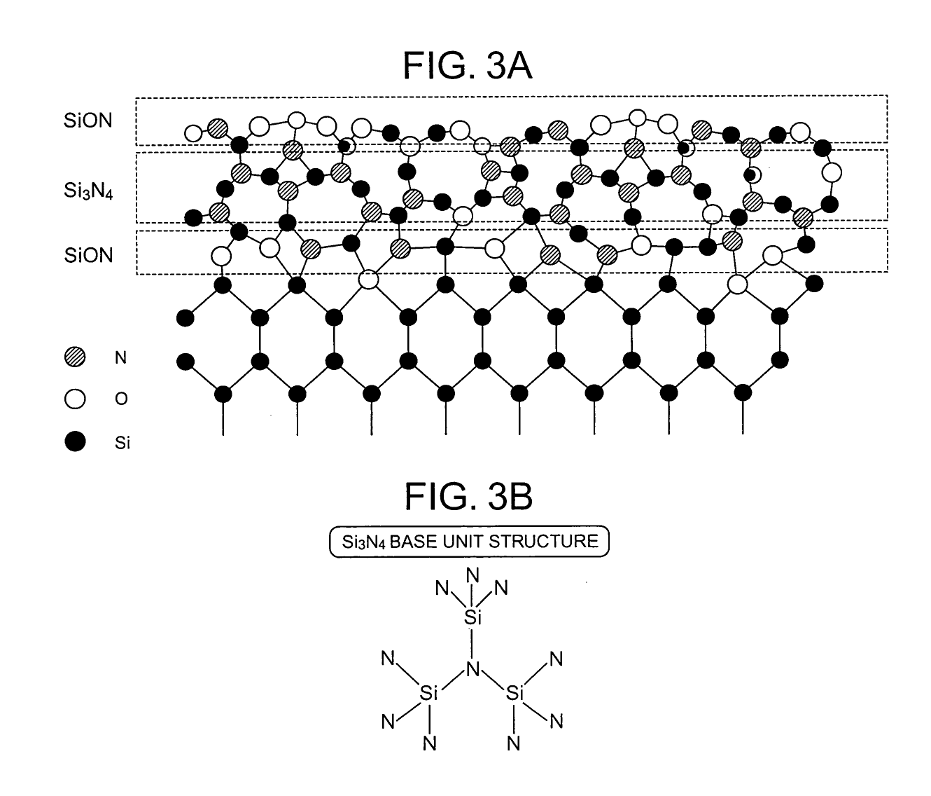

FIG. 3A is a schematic view of the atomic arrangement of the silicon oxynitride film 8. FIG. 3B shows the base unit structure of the Si₃N₄ layer. As the atom arrangement in a section taken perpendicular to the film plane is shown in FIG. 3A, only three bonding hands of Si are shown in FIG. 3A. Some N atoms have only two bonding hands shown in FIG. 3A. However, the remaining one bonding hand of Si or N exists in the direction perpendicular to the sheet plane, and therefore, is not shown in FIG. 3A.

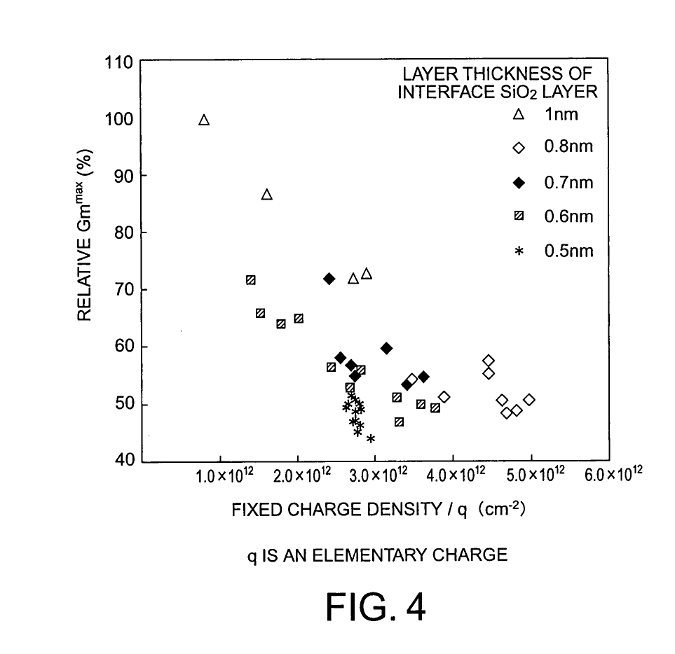

The silicon nitride layer 8a should not be in contact with the interface between the silicon oxynitride film 8a and the silicon substrate 2, and therefore, it is necessary to provide the silicon oxynitride layer 8b between the silicon oxynitride film 8a and the silicon substrate 2. If the silicon oxynitride layer 8b is not provided, the fixed charges in the silicon oxynitride film 8 cause “remote Coulomb scattering” among the carriers flowing in the channel (the portion of the silicon substrate 2 located between the source region 4a and the drain region 4b), and lowers the mobility of the electrons. Referring to FIG. 4, this phenomenon is described below.

FIG. 4 shows the properties of the ratios (relative Gm^{max}) of Gm^{max} (the maximum mutual conductance: considering the electron mobility) of a SiO₂ film formed with a single SiO₂ layer to Gm^{max} of the above silicon oxynitride film 8 in a case where the fixed charge density in the silicon oxynitride film 8 is varied while the layer thickness of the interface SiO₂ layer 8b of the silicon oxynitride film 8 is made constant. As can be seen from FIG. 4, the maximum mutual conductance Gm^{max} becomes lower, as the fixed charge density becomes higher. Also, the decrease in maximum mutual conductance Gm^{max} becomes larger, as the layer thickness of the interface SiO₂ layer 8b becomes smaller. This is because, as the distribution of the fixed charges in the silicon oxynitride film 8 becomes closer to the interface, the influence of the remote Coulomb scattering of the fixed charges on the carriers becomes larger. Also, as can be seen from FIG. 4, to obtain the same Gm^{max} as Gm^{max} of the SiO₂ film formed with a single SiO₂ layer (or to obtain a relative Gm^{max} of 100%), the fixed charge density needs to be 2×10¹¹ cm⁻² or lower where the layer thickness of the SiO₂ layer is 1 nm. This value is obtained by extrapolating the straight line (not shown) obtained by the least square fit of the four pieces of plots (indicated by white triangles), which indicates the relative Gm^{max} of 100% when the layer thickness of the SiO₂ layer is 1 nm.

Also, the layer thickness of the interface SiO₂ layer at the fixed charge density and the value of the relative Gm observed with that fixed charge density can be seen from the relationship shown in FIG. 4. For example, where the fixed charge density is 2×10¹¹ cm⁻², the relative Gm is approximately 93% when the interfacial layer thickness is 0.7 nm, and the relative Gm is approximately 100% when the interfacial layer thickness is 1 nm, as can be seen from FIG. 4. When the fixed charge density is 8×10¹¹ cm⁻², the relative Gm is approximately 88% when the layer thickness of the SiO₂ layer is 0.7 nm, and the relative Gm is approximately 95% when the interfacial layer thickness is 1 nm, as can be seen from FIG. 4. Judging from this inclination , it becomes apparent that, to obtain 100% Gm where the fixed charge density is 8×10¹¹ cm⁻², the layer thickness of the SiO₂ layer needs to be approximately 1.3 nm.

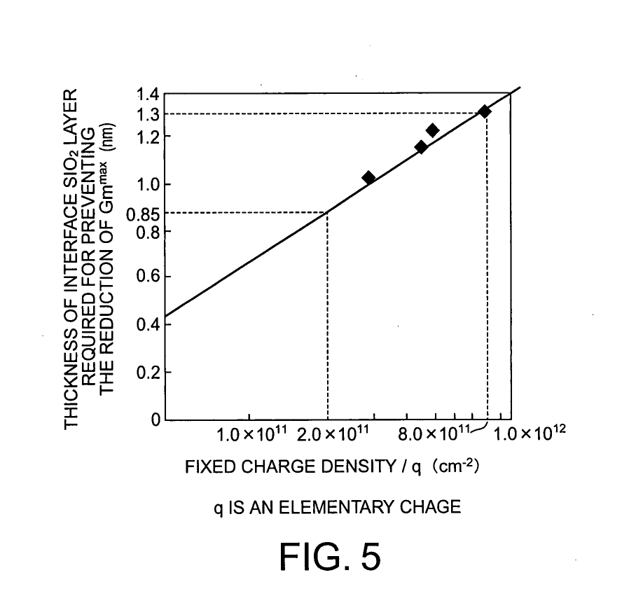

FIG. 5 shows the relationship between the fixed charge density in the silicon oxynitride film 8 and the layer thickness of the interface SiO₂ layer 8b, which is required for eliminating the influence of the remote Coulomb scattering of the fixed charges, that is, decrease in mutual conductance. To eliminate the influence of the remote Coulomb scattering, it is necessary to obtain the same Gm^{max} as the Gm^{max} of a SiO₂ film formed with a single SiO₂ layer (or to obtain the relative Gm^{max} of 100%). As can be seen from FIG. 5, the layer thickness of the interface SiO₂ layer required for eliminating the influence of the remote Coulomb scattering becomes larger, as the fixed charge density becomes higher. However, there is an upper limit and a lower limit set for the layer thickness of the interlayer SiO₂ layer, so as to eliminate the problem of the writing electric field and the influence of the remote Coulomb scattering due to the fixed charges in the oxynitride film. This aspect is described below.

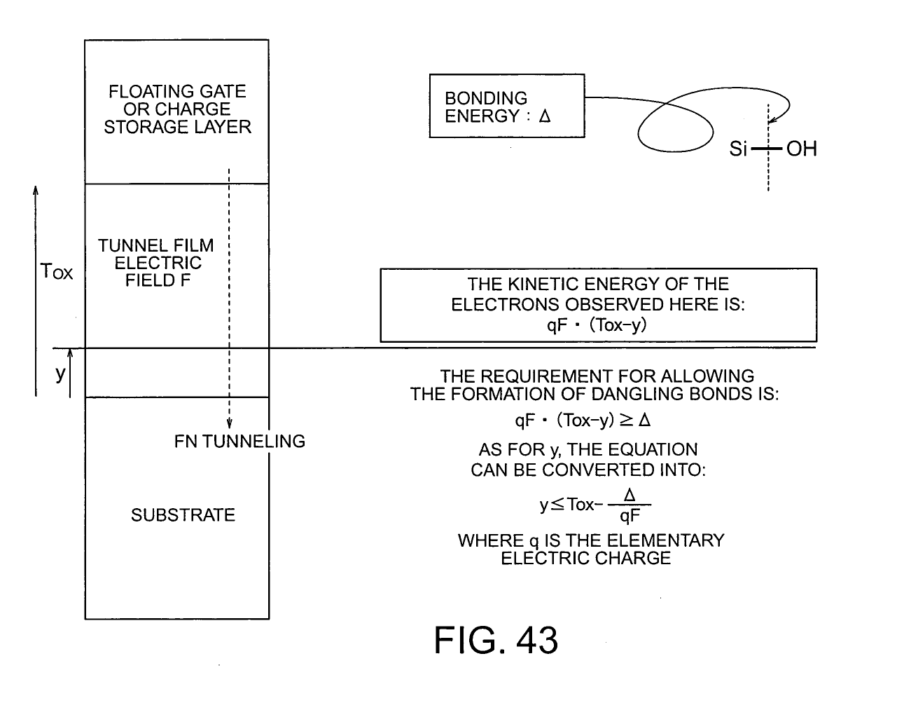

As shown in FIG. 43, when written electrons are discharged by a FN tunneling effect (when data is erased), an electric field F is induced. Where Tox represents the film thickness of the tunnel film, a certain point in the tunnel film is Y nm away from the substrate, and q represents the elementary electric charge, the kinetic energy of the electrons reaching the point Y after the FN tunneling is expressed as qF(Tox−Y). With the binding energy of Si—OH bonds being Δ, the requirement for the formation of dangling bonds is expressed as qF(Tox−Y)≧Δ. As for Y, this expression can be converted into Y≦Tox−Δ/(qF). Accordingly, the Si—OH bonds existing within Tox−Δ/(qF) from the interface turn into dangling bonds. In other words, the area existing between the substrate interface and the point in the tunnel film at the distance of Δ/(qF) from the interface between the tunnel film and the floating gate (or the charge storage layer) is the “vital area” in which the Si—OH bonds existing therein turn into dangling bonds. Therefore, the bonds existing in this area should be reinforced with nitrogen. Meanwhile, Δ/(qF) is equal to or smaller than the total thickness of the silicon oxide film 10 and the silicon oxynitride layer 8c. Accordingly, the silicon nitride layer 8a is separated from the interface between the insulating film 6 and the charge storage layer 12 at least by the distance equivalent to the value obtained by dividing the binding energy of silicon and hydroxyl by the electric field F and the elementary charge q in the insulating film 6. Here, the silicon oxynitride layer 8b or the silicon oxynitride layer 8c may contain F (fluorine) or deuterium.

The area in which bonds are reinforced by nitrogen becomes narrower when the electric field (F) is made weaker, and writing in that area cannot be performed when the electric field (F) is made weaker. Therefore, with the use of the minimum electric field Fmin for writing, the upper limit for Y is determined by a function only involving Δ and Tox. For instance, Ymax is 1.6 nm, where Tox is 6 nm, Δ is 3.6 eV, and Fmin is 10 MV/cm². Since the range of Ymax=1.6 nm from the substrate interface becomes the vital area in which dangling bonds are formed, the region within this range should be turned into a nitride film. However, as Gm is reduced by the remote Coulomb scattering due to the fixed charges, the layer thickness of the interface SiO₂ layer should be made as thick as possible. Since the unit layer thickness of a nitride layer is approximately 0.3 nm, the upper limit for the layer thickness of the interface SiO₂ layer is 1.3 nm (=1.6-0.3). To form an SiO₂ layer having a layer thickness of 1.3 nm or smaller while restraining the influence of the remote Coulomb scattering, the upper limit for the fixed charge density is 8×10¹¹ cm⁻² or lower, as can be seen from FIG. 5. Those values of course vary with Fmin and Tox, and represent the values observed in typical cases. The binding energy of silicon and hydroxyl varies under the influence of the substance in which the bonds exist. The binding energy of silicon and hydroxyl is approximately 3.6 eV under the process conditions for forming the tunnel film of this embodiment.

Next, the lower limit set for the layer thickness of the interface SiO₂ layer is described. We discovered that the fixed charge density in an oxynitride film after oxidation can be reduced to approximately 2.0×10¹¹ cm⁻² in a case where the film formation is carried out in an atmosphere in which the rate of the partial pressure of the nitriding gas to the sum of the partial pressure of the diluent gas and the partial pressure of the nitriding gas is 5 or higher, and the total pressure of 40 Torr or lower (more specifically, in a case where the atmosphere is a mixed atmosphere of a N₂ gas as a diluent gas with a partial pressure of 30 Torr and a NH₃ gas as a nitriding gas with a partial pressure of 0.03 Torr, and the surface of the silicon substrate 2 is set at 700° C. and is maintained at 700° C. for 100 seconds). Meanwhile, to restrain the remote Coulomb scattering, the layer thickness of the interface SiO₂ layer needs to be at least 0.85 nm. Accordingly, the lower limit for the layer thickness of the interface SiO₂ layer is 0.85 nm. This also means that the silicon nitride layer 8a is at least 0.85 nm away from the semiconductor substrate 2.

Here, the method for controlling the fixed charge density is described. The fixed charge density in the silicon oxynitride film 8 is proportional to the density of dangling bonds formed from broken Si—N bonds. The dangling bond density is proportional to the product of the Si—N bond density and the generation rate of dangling bonds. If the number of Si—N bonds does not greatly vary, the dangling bond density largely depends on the generation rate of dangling bonds. Accordingly, to control the fixed charge density in the silicon oxynitride film 8, the generation rate of dangling bonds should be controlled. To control the generation rate of dangling bonds, the temperature for nitridation and the pressure of the nitriding gas should be controlled as described above. For instance, since the upper limit of the fixed charge density is 8×10¹¹ cm⁻², we can conclude that the generation rate is 2.0×10⁻⁴ (=8.0×10¹¹ cm⁻²/4.0×10¹⁵ cm⁻²). To achieve such a generation rate, the nitriding temperature should be 700° C., and a nitride film should be formed in an atmosphere in which the ratio of the partial pressure of the nitriding gas is 5, and the total pressure is 40 Torr. Here, the value of 4.0×10¹⁵ cm⁻² is the concentration of Si—N bonds in the silicon nitride film. Where the fixed charge density is 2×10¹¹ cm⁻², which is the lower limit for the fixed charge density, the generation rate is 0.5×10⁻⁴ (=2.0×10¹¹ cm⁻²/4.0×10¹⁵ cm⁻²). To achieve such a generation rate, the nitriding temperature should be 700° C., and a nitride film should be formed in an atmosphere in which the ratio of the partial pressure of the nitriding gas is 1000, and the total pressure is 30 Torr. To control the fixed charge density so that the generation rate (=fixed charge density/Si—N bond density) achieved in this embodiment falls in the range of 0.5×10⁻⁴ to 2.0×10⁻⁴, it is effective to control the nitriding temperature, the dilution rate of the nitriding gas, and the total pressure.

As described above, the layer thickness required for the interface SiO₂ layer 8b when the fixed charge density in the silicon oxynitride film 8 is 2.0×10¹¹ cm⁻² is 0.85 nm or more. Accordingly, the distance h (see FIG. 1) from the interface between the silicon oxynitride film 8 and the silicon substrate 2 to the center of the layer thickness of the silicon nitride layer 8a is 1.0 nm (=0.85 nm+0.15 nm) to 1.45 nm (=1.3 nm+0.15 nm), as the layer thickness of the silicon nitride layer 8a is approximately 0.3 nm. As long as the silicon oxynitride layer 8b and the silicon oxynitride layer 8c have the same layer thickness, the film thickness of the silicon oxynitride film 8 is 2.0 nm to 2.9 nm.

In this embodiment, the fixed charge density x in the silicon oxynitride film 8 and the layer thickness y required for the interface SiO₂ layer 8b to prevent a decrease in mutual conductance satisfy the following equation:

y=α·Ln(x)−β

where Ln represents a natural logarithm, α is equal to or smaller than 0.35, and β is equal to or smaller than 8. Therefore, it is necessary to set the nitrogen concentration in the silicon oxynitride film 8, the oxygen concentration in the interface, and the layer thickness of the interface oxynitride layer, so as to satisfy the above equation.

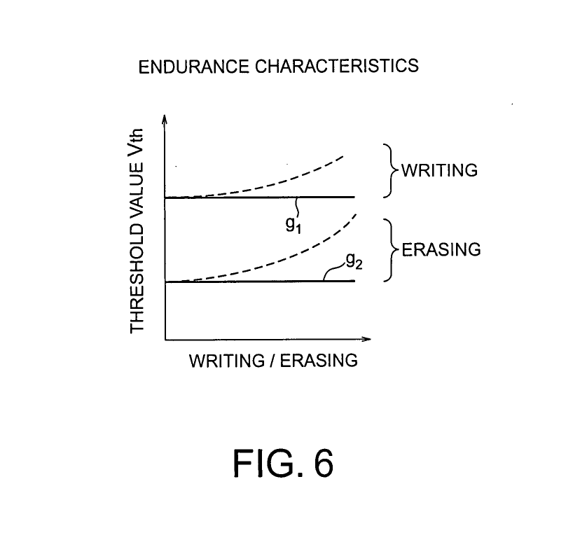

In FIG. 6, the line g₁ schematically depicts the endurance (the endurance characteristics) observed after writing/erasing is repeated in the semiconductor memory device of this embodiment, and the line g₂ shows the endurance characteristics observed after erasing is performed. The broken lines represent the endurance characteristics of a comparative example. In this comparative example, a SiO₂ film formed with a single SiO₂ layer is used as the tunnel insulating film in a semiconductor memory device having the same structure as the semiconductor memory device of this embodiment. As can be seen from FIG. 6, the semiconductor memory device of this embodiment can avoid degradation of the endurance characteristics.

Referring back to FIG. 1, a method for manufacturing the semiconductor memory device of this embodiment is described.

First, the substrate 2 doped with the desired impurities is prepared. After appropriate surface treatment is carried out, the above described high-quality silicon oxynitride film 8 is formed. The method for forming the high-quality silicon oxynitride film 8 will be described in detail in the embodiments described later. In this description, the film thickness of the silicon oxynitride film 8 is approximately 2 nm. The silicon oxide film 10 of 2 nm to 6 nm is then formed by CVD. If the oxide film 10 formed by CVD is made too thick, a thinner oxide film than a conventional tunnel oxide film (approximately 10 nm in film thickness) cannot be obtained. If the oxide film 10 is made too thin, on the other hand, the data retention properties may deteriorate. Therefore, the film thickness of the silicon oxide film 10 of this embodiment is 2 nm to 6 nm. By adjusting the oxide film 10 formed by CVD, the tunnel insulating film 6 can be adjusted as a whole. The film thickness adjustment can be relatively easily carried out in a regular semiconductor process today. Accordingly, the preferred film thickness for the tunnel insulating film 6 of this embodiment is 4 nm (=2 nm+2 nm) to 8.9 nm (2.9 nm+6 nm).

A polysilicon film 12 to be the floating gate is then formed. The interelectrode insulating film 14 and the control gate 16 are then formed in this order according to the process for manufacturing a conventional NAND flash memory. The interelectrode insulating film 14 may be a stacked structure including an oxide film and a nitride film, or a stacked structure including a high-permittivity film or a high-permittivity material. The control gate 16 may be made of polysilicon, a silicide, or a metal. The tunnel insulating film 6, the floating gate 12, the interelectrode insulating film 14, and the control gate 16 are then patterned into a gate shape. After that, impurities are injected into the silicon substrate at both sides of the gate, if necessary, so as to form the source region 4a and the drain region 4b.

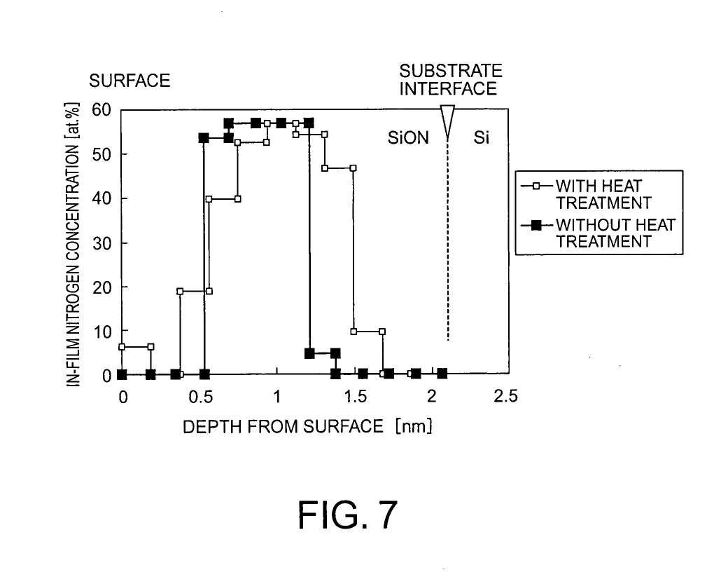

The results of measurement carried out on the nitrogen concentration profile of the silicon oxynitride film 8 of this embodiment are indicated by black dots in FIG. 7. To form the silicon oxynitride film 8 of this embodiment, it is necessary to carry out heat treatment, as will be described later. For the purpose of comparison, the results of measurement carried out on the nitrogen concentration profile of a silicon oxynitride film for which heat treatment is not carried out are indicated by white dots in FIG. 7. As can be seen from FIG. 7, in the silicon oxynitride film 8 of this embodiment, the interface SiO₂ layer 8b not containing nitrogen exists within 1 nm from the interface with the silicon substrate 2, and an oxygen rich layer exists and sandwiches a region with zero oxygen concentration (the silicon nitride layer 8a). The total physical film thickness is 2 nm to 2.9 nm. As described above, in this embodiment, it is essential to have the oxide layer that does not contain nitrogen and is formed on the surface side (the floating gate side). With this arrangement, electrons are not trapped between the silicon oxynitride film 8 and the oxide film 14 formed by CVD.

As described above, in accordance with this embodiment, a semiconductor memory device having a thin tunnel insulating film that does not degrade the endurance (the endurance characteristics) when writing/erasing is repeated can be provided.

### Second Embodiment

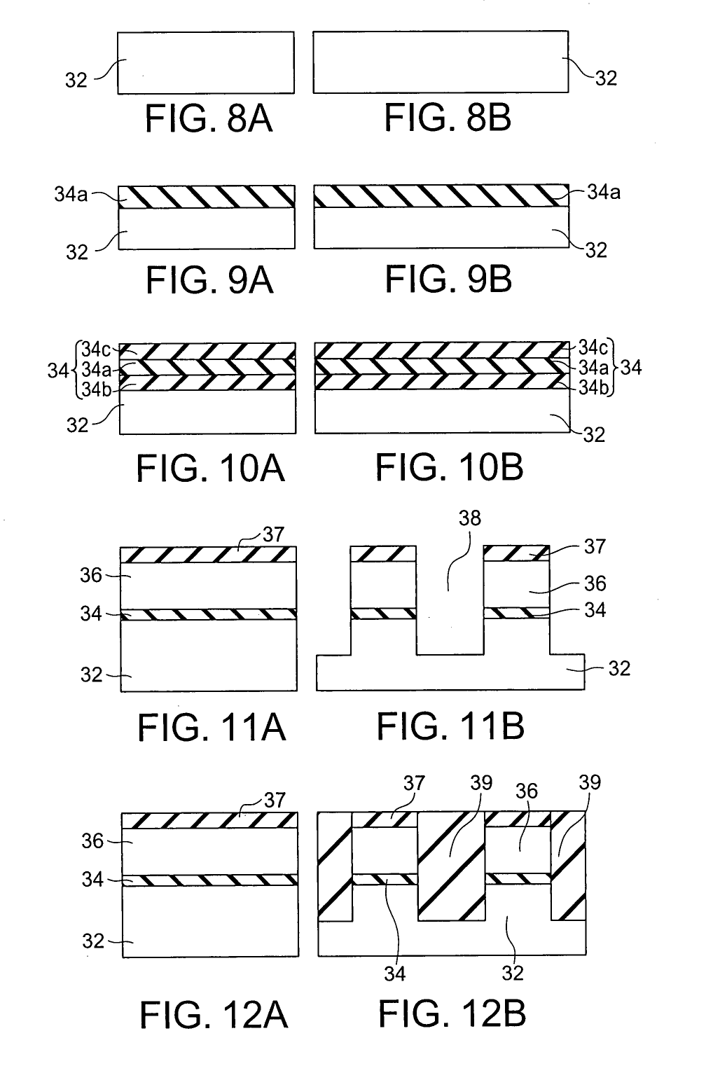

Next, a method for manufacturing a semiconductor memory device in accordance with a second embodiment of the present invention is described. The semiconductor memory device to be manufactured by the manufacturing method of this embodiment is nonvolatile memory cells that include FG (floating gate). Referring to FIGS. 8A through 15B, the method for manufacturing the memory of this embodiment is described. FIGS. 8A through 15B are cross-sectional views showing the manufacturing procedures in accordance with this embodiment. The cross section shown in each of FIGS. 8A, 9A, 10A, 11A, 12A, 13A, 14A, and 15A is perpendicular to the cross section shown in each of FIGS. 8B, 9B, 10B, 11B, 12B, 13B, 14B, and 15B.

First, as shown in FIGS. 8A and 8B, a silicon substrate 32 doped with desired impurities is subjected to a diluted HF treatment, and the surface of the silicon substrate 32 is terminated by hydrogen. After that, the silicon substrate 32 is placed in the chamber of a film forming apparatus. After the atmosphere in the chamber is adjusted to a gas (such as a nitrogen gas) that does not react with or etch silicon during the manufacturing process, the temperature of the silicon substrate 32 is increased to 700° C., so as to remove hydrogen from the silicon substrate 32.

The atmosphere of the chamber is then changed to N₂ with a partial pressure of 30 Torr or NH₃ with a partial pressure of 0.03 Torr, for example, and the surface of the silicon substrate 32 is heated to 700° C. and is maintained at 700° C. for 100 seconds. By doing so, a silicon nitride layer 34a is formed on the silicon substrate 32, as shown in FIGS. 9A and 9B. By the manufacturing method in accordance with this embodiment, a nitrogen gas NH₃ diluted with a N₂ gas is used for forming the silicon nitride layer 34a. By diluting the nitrogen gas NH₃ with a diluent gas N₂, the silicon nitride layer 34a can be a high-quality layer that does not have a defect and has few Si—N—H bonds that might cause Si—O—H bonds after oxidation. This forming method was invented by the inventors of the present invention, and a patent application concerning this method has been filed (Japanese Patent Application No. 2006-176863).

The temperature of the silicon substrate 32 is then increased to and maintained at 850° C. While the temperature of the silicon substrate 32 is maintained at 850° C., the atmosphere in the chamber is changed to N₂ with a partial pressure of 30 Torr and O₂ with a partial pressure of 3 Torr, and the changed atmosphere is maintained at 300 seconds. Accordingly, a silicon oxynitride layer 34b containing oxygen is formed between the silicon substrate 32 and the silicon nitride layer 34a, and a silicon oxynitride layer 34c containing oxygen is formed on the silicon nitride layer 34a. Thus, a tunnel insulating film 34 consisting of the silicon oxynitride layer 34b, the silicon nitride layer 34a, and the silicon oxynitride layer 34c is formed, as shown in FIGS. 10A and 10B. The silicon oxynitride film 8 of the first embodiment can be formed in the same manner as the tunnel insulating film 34.

A 60-nm thick phosphorus-doped polycrystalline silicon layer 36 that is to be a floating gate, and a mask material 37 to be used for the device isolating process are deposited in this order by CVD (Chemical Vapor Deposition). Etching is then performed on the mask material 37, the polycrystalline silicon layer 36, and the tunnel insulating film 34 by RIE (Reactive Ion Etching) using a resist mask (not shown). Etching is further performed on the exposed regions of the silicon substrate 32, so as to form device isolating grooves 38 of 100 nm in depth (see FIGS. 11A and 11B).

A silicon oxide film 39 for the device isolation is deposited on the entire surface, so as to fill the device isolating grooves 38. The portions of the silicon oxide film 39 existing on the surface are removed by CMP (Chemical Mechanical Polishing), so as to flatten the surface. As a result, the mask material 37 is exposed (see FIGS. 12A and 12B).

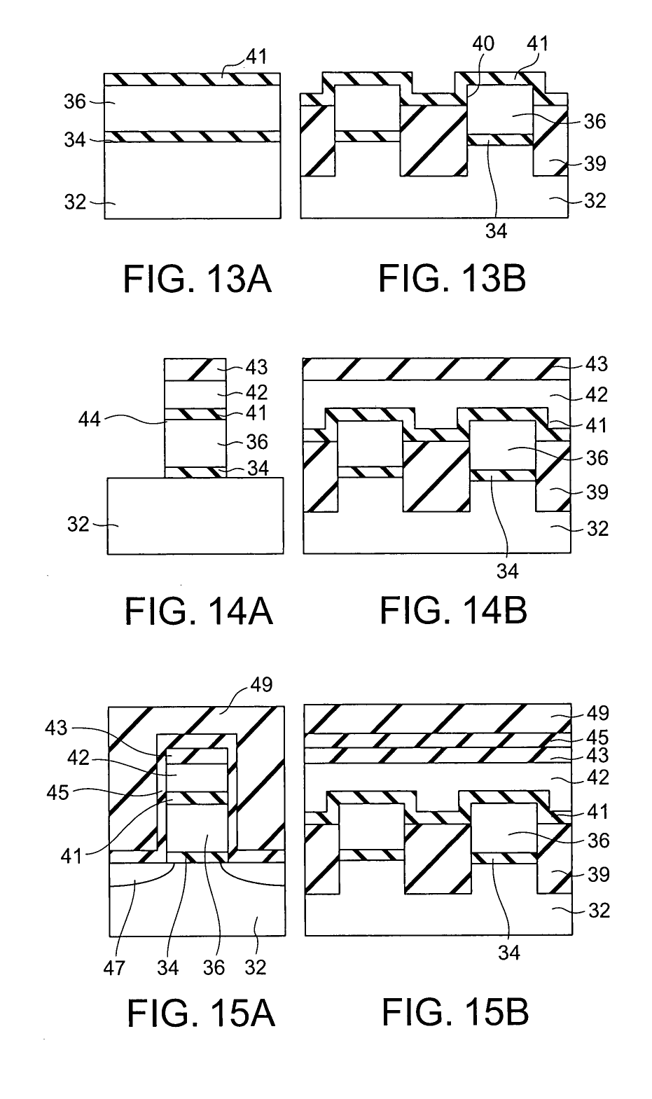

After the exposed mask material 37 is selectively removed by etching, the exposed surface of the silicon oxide film 39 is removed by etching with a diluted hydrofluoric acid solution, so as to expose a portion of each side face 40 of the polycrystalline silicon layer 36. After that, a 15-nm thick alumina film to be an interelectrode insulating film is deposited by ALD (Atomic Layer Deposition) on the entire surface. Because of the oxidizing agent used for the film formation by ALD, an extremely thin silicon oxide layer is formed in the interface between the alumina film and the polycrystalline silicon layer 36, and a 16-nm thick interelectrode insulating film 41 having a two-layer structure consisting of an alumina film and a silicon oxide layer is formed (see FIGS. 13A and 13B).

A 100-nm thick conductive layer 42 that has a two-layer structure consisting of a tungsten silicide layer and a polycrystalline silicon layer and is to be a control gate is deposited by CVD, and a RIE mask material 43 is deposited by CVD. After that, etching is performed on the mask material 43, the conductive layer 42, the interelectrode insulating film 41, the polycrystalline silicon layer 36, and the tunnel insulating film 34 by RIE using a resist mask (not shown), so as to form slits 44 extending in the word line direction. In this manner, the polycrystalline silicon layer 36 to be the floating gate and the conductive layer 42 to be the control gate are shaped (see FIGS. 14A and 14B).

Lastly, after a silicon oxide film 45 called an electrode sidewall oxide film is formed on the exposed face by thermal oxidation, a source/drain diffusion layer 47 is formed by ion implantation, and an interlayer insulating film 49 to cover the entire surface is formed by CVD. After that, a wiring layer and the likes are formed by a well-known method, and nonvolatile memory cells are completed (see FIGS. 15A and 15B).

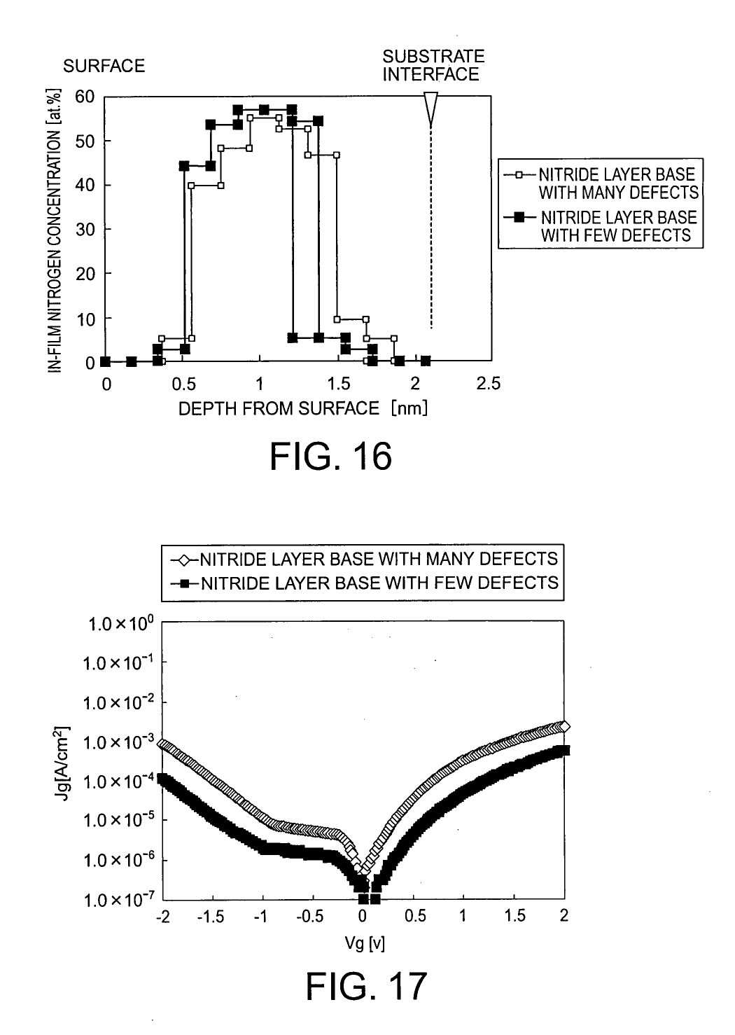

In the silicon nitride layer 34a of the tunnel insulating film 34 formed in the above manner, there are strong Si—N bonds. By carrying out the process for strengthening the Si—N bonds as in the manufacturing method in accordance with this embodiment, improvement of the charge retention properties can be expected as described below. FIGS. 16 and 17 show the difference in SILC (Stress Induced Leakage Current) due to the difference in the conditions for forming the silicon oxynitride film. FIG. 16 shows the in-film nitrogen profiles of 2-nm thick silicon oxynitride films (SiON films). In FIG. 16, the “nitride layer base with many defects” refers to a SiON film formed by oxidizing a silicon nitride layer with many defects formed by plasma-nitriding a silicon substrate at room temperature, and the “nitride layer base with few defects” refers to a SiON film formed by oxidizing a silicon nitride layer with few defects formed with the use of a N₂ gas with a partial pressure of 30 Torr and a NH₃ gas with a partial pressure of 0.03 Torr at 700° C. FIG. 17 shows the J-V characteristics of the SiON films. In FIG. 17, the abscissa axis indicates the gate voltage Vg, and the ordinate axis indicates the leakage current Jg. As can be seen from FIG. 17, by forming a silicon nitride layer with few defects, the total leakage current is reduced.

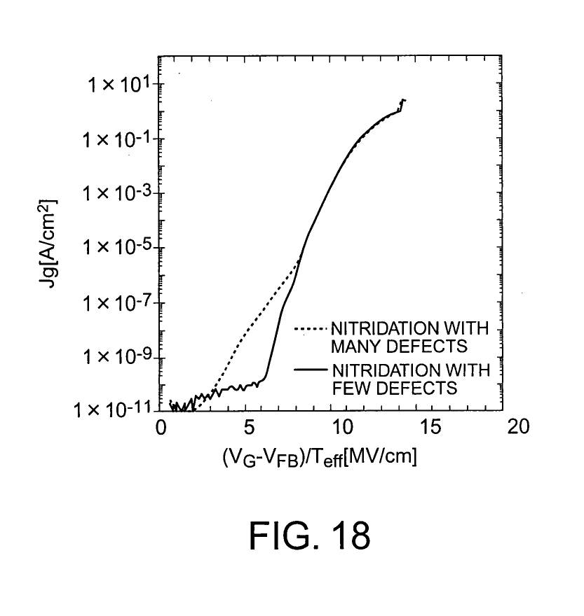

FIG. 18 shows the J-V characteristics of insulating films formed by depositing 3-nm thick SiO₂ films on the 2-nm thick SiON films shown in FIG. 17. As can be seen from FIG. 18, the leakage current in the low-voltage area in the case where a SiON film formed on base that is a silicon nitride layer with few defects as in this embodiment is placed on the substrate interface side is dramatically lower than in the case where a SiON film is formed on a base that is a silicon nitride layer with many defects formed by plasma-nitriding a silicon substrate at room temperature. In FIG. 18, the abscissa axis indicates the value obtained by dividing the difference between the gate voltage V_{G} and the flat-band voltage V_{FB} by the electrically effective film thickness T_{eff} of each transistor, and the ordinate axis indicates the leakage current Jg. The value (V_{G}−V_{FB})/T_{eff} on the abscissa axis indicates the electric field induced in the insulating film. With this arrangement, the influence of the fixed charges in each tunnel insulating film can be eliminated, and the insulation properties of the two films can be compared with each other with respect to the field strength induced in each tunnel insulating film. This is because, since the flat-band voltage V_{FB} shifts with the fixed charge amount in the tunnel insulating film, the electric field induced in the tunnel insulating film is wrongly estimated if the comparison is carried out only with respect to the gate voltage V_{G}.

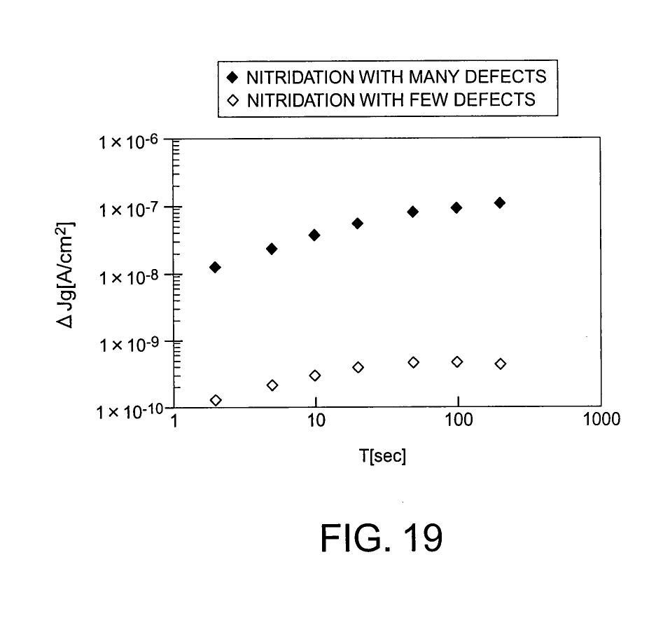

FIG. 19 shows the charge retention properties of memory cells having different SILC characteristics from each other. As can be seen from FIG. 19, the leakage current under the low-voltage stress is reduced by forming a high-quality nitride layer with few defects, and the charge retention properties are greatly improved accordingly. Such results are obtained because generation of defects at the time of writing/erasing is restrained by forming a tight network between Si and N, and the number of leakage paths formed in the bulk is reduced.

Accordingly, a silicon oxynitride film (SiON film) with few defects and high reliability can be formed by the manufacturing method in accordance with this embodiment.

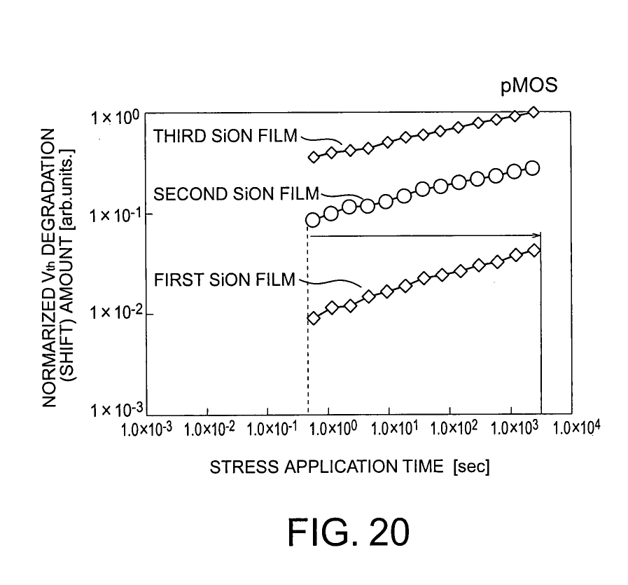

Referring now to FIG. 20, another example indicating that a SiON film formed by the manufacturing method in accordance with this embodiment has very strong Si—N bonds is described. FIG. 20 is a graph indicating the dependence of the threshold voltage on the stress voltage application time or a graph indicating the NBTI (Negative Bias Temperature Instability) characteristics observed where a stress voltage is applied to each of first through third SiON films serving as the tunnel insulating films of p-MOS transistors. The first SiON film is produced by forming a silicon nitride layer with the use of a N₂ gas with a partial pressure of 30 Torr and a NH₃ gas with a partial pressure of 0.03 Torr at a nitridation temperature of 700° C., and then oxidizing the silicon nitride layer at 850° C., as in this embodiment. The second SiON film is produced by forming a silicon nitride layer with the use of a N₂ gas with a partial pressure of 30 Torr and a NH₃ gas with a partial pressure of 30 Torr at a nitridation temperature of 700° C., and then oxidizing the silicon nitride layer at 850° C. The third SiON film is produced by oxidizing a silicon nitride layer having many defects formed by plasma-nitriding a silicon substrate at room temperature. Accordingly, the first SiON film has a high-quality silicon nitride layer with few defects. The second SiON film has fewer defects than the third SiON film, as the nitriding gas for forming a silicon nitride layer is diluted. However, the second SiON film has more defects than the first SiON film formed by the manufacturing method in accordance with this embodiment. The third SiON film is a SiON film formed on a base that is a silicon nitride layer with many defects formed by plasma-nitriding a silicon substrate, at room temperature for example. As can be seen from FIG. 20, the NBTI characteristics are dramatically improved by forming a silicon nitride layer with few defects, forming a SiO₂ layer in the interface through the silicon nitride layer, and reducing the defects in the film. Such results are achieved, as the defects in the SiON film is reduced by forming a tight network between Si and N, and generation of new defects at the time of stress application is restrained. Accordingly, by the manufacturing method in accordance with this embodiment, a SiON film with few defects and high reliability can be produced.

As described above, in accordance with this embodiment, Si—N bonds are formed in the silicon nitride layer 34a, and few Si—N—H bonds that might cause Si—O—H bonds at the time of oxidation exist in the silicon nitride layer 34a. Accordingly, dangling bonds are not easily formed even when writing/erasing is repeated, and degradation of the endurance characteristics can be prevented. The silicon nitride layer 34a is approximately 0.3 nm in layer thickness, and 55% to 57% in nitrogen concentration. Accordingly, the silicon nitride layer 34a is substantially made of Si₃N₄, with the first-neighbor atoms of the silicon being nitrogen atoms, and the second-neighbor atoms being silicon atoms. The nitrogen concentration of the silicon oxynitride layers 34b and 34c is 10% or lower, and are substantially silicon oxide layers (SiO₂ layers). If necessary, a silicon oxide film of 2 nm to 6 nm may be formed by CVD on the oxynitride film 34c.

### Third Embodiment

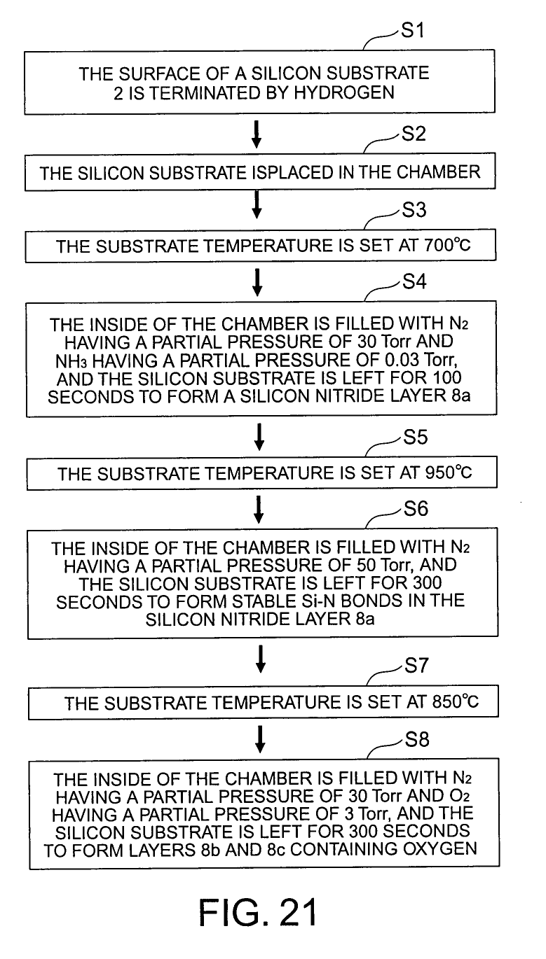

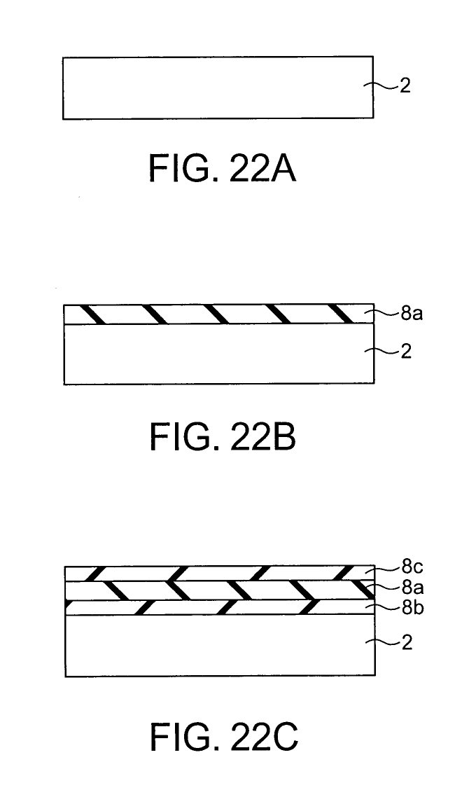

Referring now to FIG. 21, FIG. 22A, FIG. 22B, and FIG. 22C, a method for manufacturing a semiconductor memory device in accordance with a third embodiment of the present invention is described. The manufacturing method in accordance with this embodiment involves the same procedure as the procedure for forming the silicon oxynitride film 8 of the semiconductor memory device in accordance with the first embodiment shown in FIG. 1, except that a diluted gas is mixed with a nitride film formed on the silicon substrate, and a silicon oxynitride film having a smaller fixed charge amount than a conventional silicon oxynitride film is formed. FIG. 21 is a flowchart showing the procedures in the manufacturing method in accordance with this embodiment. FIGS. 22A through 22C are cross-sectional views illustrating manufacturing procedures.

A silicon substrate 2 is subjected to a diluted HF treatment, and the surface of the silicon substrate 2 is terminated by hydrogen (step S1 of FIG. 21, FIG. 22A). The silicon substrate 2 is then placed in a film forming chamber (step S2). The inside of the chamber is filled with a mixed atmosphere of a N₂ gas as a diluent gas with a partial pressure of 30 Torr and a NH₃ gas as a nitriding gas with a partial pressure of 0.03 Torr, and the surface of the silicon substrate 2 is heated to 700° C. and is maintained at 700° C. for 100 seconds. By doing so, a silicon nitride layer 8a is formed on the silicon substrate 2 (steps S3 and S4, FIG. 22B).

The atmosphere in the chamber is then changed to a N₂ gas with a partial pressure of 50 Torr, and the surface of the silicon substrate 2 is heated to 950° C. and is maintained at 950° C. for 300 seconds (steps S5 and S6). As a result of this, the dangling bonds in the silicon nitride layer 8a are bonded with nitrogen atoms, and stable Si—N bonds are formed in the silicon nitride layer 8a.

The inside of the chamber is then changed to a mixed atmosphere of a N₂ gas as a diluent gas with a partial pressure of 30 Torr and an O₂ gas as an oxidizing gas with a partial pressure of 3 Torr, and the surface of the silicon substrate 2 is set at 850° C. and is maintained at 850° C. for 300 seconds (steps S7 and S8). By doing so, a silicon oxynitride layer 8b containing oxygen is formed between the silicon substrate 2 and the silicon nitride layer 8a, and a silicon oxynitride layer 8c containing oxygen is formed on the surface of the silicon nitride layer 8a (FIG. 22C).

The effect of the heat treatment is now described. FIG. 7 shows the difference in oxygen distribution between a silicon oxynitride film oxidized after a heat treatment following the formation of a silicon nitride layer and a silicon oxynitride film oxidized without a heat treatment following the formation of a silicon nitride layer. As can be seen from FIG. 7, the heat treatment increases the oxygen amount in the interface between the silicon oxynitride film and the silicon substrate, and reduces the film thickness after the oxidation. This is because, as the number of defects in the silicon oxynitride film becomes smaller by virtue of the heat treatment, the probability of oxygen detachment due to defects becomes lower, and the oxygen is not easily absorbed in the silicon oxynitride film.

On the other hand, the bonds in the interface between the silicon oxynitride film and the silicon substrate become weaker due to the structural stress, and the diffused oxygen is detached, resulting in oxidation. Accordingly, an ideal silicon oxynitride film having a large oxygen distribution on the interface side and a large nitrogen distribution on the surface side can be formed.

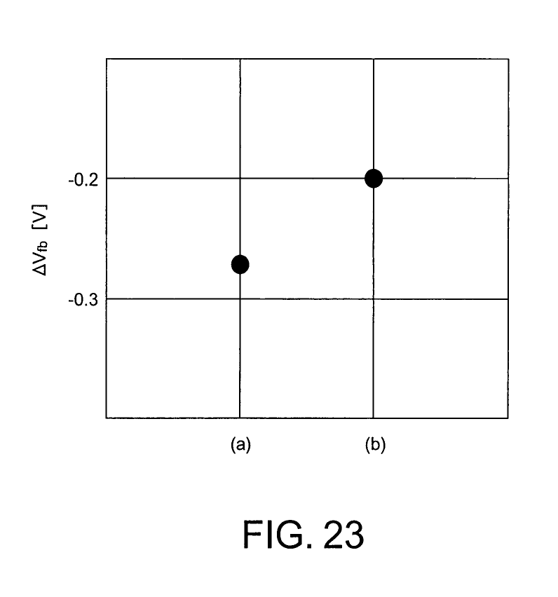

FIG. 23 shows the shift amounts ΔV_{Fb} of the p-MOS flat-band voltages of (a) a 2-nm thick silicon oxynitride film oxidized without a heat treatment after the formation of a silicon nitride layer and (b) a 2-nm thick silicon oxynitride film oxidized after a heat treatment following the formation of a silicon nitride layer. The film thickness of each of the silicon oxynitride films (a) and (b) is a physical film thickness. As can be seen from the comparison between (a) and (b), the shift amount ΔV_{Fb} is improved by the heat treatment. This is because the number of defects in the film (b) is reduced by virtue of the heat treatment, and a nitrogen distribution indicating that the nitrogen is distributed on the surface side or that the charge distribution is mostly seen on the surface side, as the oxidation in the surface and in the film is restrained.

As described above, in accordance with this embodiment, by carrying out a heat treatment after nitridation, a silicon oxynitride film (SiON film) having the interface oxidized first can be formed. Thus, a silicon oxynitride film (SiON film) having excellent reliability can be formed. In the silicon nitride layer 8a of this silicon oxynitride film, Si—N bonds are formed, but few Si—O—H bonds exist, as mentioned in the first embodiment. Accordingly, by employing such a silicon oxynitride film of this embodiment as the tunnel insulating film of a flash memory, for example, formation of dangling bonds is restrained even when writing/erasing is repeated, and degradation of the endurance characteristics can be prevented. Also, the silicon nitride layer 8a is approximately 0.3 nm in layer thickness, and 55% to 57% in nitrogen concentration. Accordingly, the silicon nitride layer 8a is substantially made of Si₃N₄, with the first-neighbor atoms of the silicon being nitrogen atoms, and the second-neighbor atoms being silicon atoms. The nitrogen concentration of the silicon oxynitride layers 8b and 8c is 10% or lower, and are substantially silicon oxide layers (SiO₂ layers).

### Fourth Embodiment

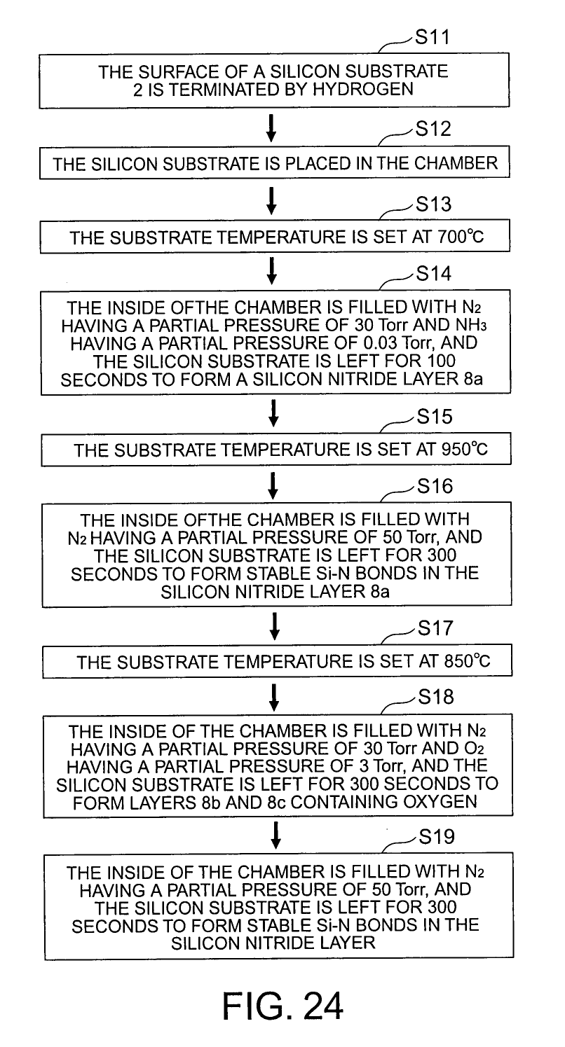

Referring now to FIG. 24, FIG. 22A, FIG. 22B, and FIG. 22C, a method for manufacturing a semiconductor memory device in accordance with a fourth embodiment of the present invention is described. The manufacturing method in accordance with this embodiment involves the same procedure as the procedure for forming the silicon oxynitride film 8 of the semiconductor memory device in accordance with the first embodiment shown in FIG. 1, except that a diluted gas is mixed with a nitride film formed on the silicon substrate, and a silicon oxynitride film having a smaller fixed charge amount than a conventional silicon oxynitride film is formed. FIG. 24 is a flowchart showing the procedures in the manufacturing method in accordance with this embodiment.

A silicon substrate 2 is subjected to a diluted HF treatment, and the surface of the silicon substrate 2 is terminated by hydrogen (step S11, FIG. 22A). The silicon substrate 2 is then placed in a film forming chamber (step S12). The inside of the chamber is filled with a mixed atmosphere of a N₂ gas as a diluent gas with a partial pressure of 30 Torr and a NH₃ gas as a nitriding gas with a partial pressure of 0.03 Torr, and the surface of the silicon substrate 2 is heated to 700° C. and is maintained at 700° C. for 100 seconds. By doing so, a silicon nitride layer 8a is formed on the silicon substrate 2 (steps S13 and S14, FIG. 22B).

The atmosphere in the chamber is then changed to a N₂ gas with a partial pressure of 50 Torr, and the surface of the silicon substrate 2 is heated to 950° C. and is maintained at 950° C. for 300 seconds (steps S15 and S16). As a result of this, the dangling bonds in the silicon nitride layer 8a are bonded with nitrogen atoms, and stable Si—N bonds are formed in the silicon nitride layer 8a.

The inside of the chamber is then changed to a mixed atmosphere of a N₂ gas as a diluent gas with a partial pressure of 30 Torr and an O₂ gas as an oxidizing gas with a partial pressure of 3 Torr, and the surface of the silicon substrate 2 is set at 850° C. and is maintained at 850° C. for 300 seconds (steps S17 and S18). By doing so, a silicon oxynitride layer 8b containing oxygen is formed between the silicon substrate 2 and the silicon nitride layer 8a, and a silicon oxynitride layer 8c containing oxygen is formed on the surface of the silicon nitride layer 8a (FIG. 22C). In this manner, a silicon oxynitride film 8 having the silicon oxynitride layer 8b, the silicon nitride layer 8a, and the silicon oxynitride layer 8c stacked in this order is formed on the silicon substrate 2.

The atmosphere in the chamber is then changed to a N₂ gas with a partial pressure of 50 Torr, for example, and the surface of the silicon substrate 2 is heated to 950° C. and is maintained at 950° C. for 300 seconds (step S19). As a result of this, the dangling bonds in the silicon nitride layer 8a and the silicon oxynitride layers 8b and 8c are again bonded with one another, and the number of defects in the silicon oxynitride film 8 becomes smaller.

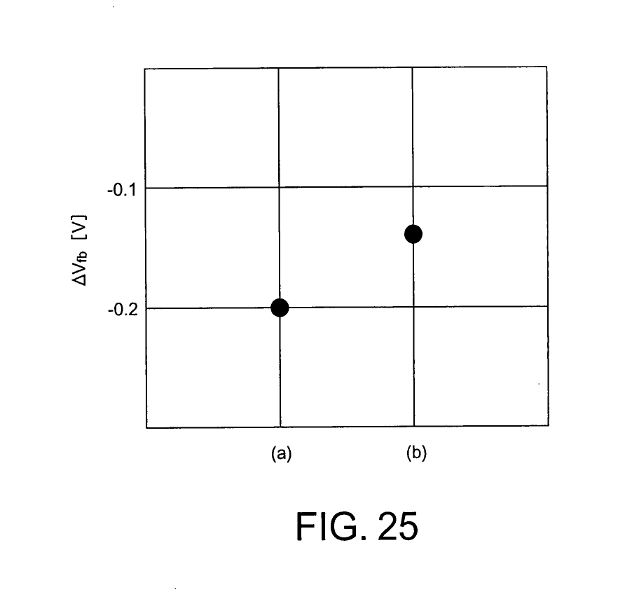

The effect of the heat treatment of step S19 is now described. FIG. 25 shows the shift amounts ΔV_{Fb} of the flat-band voltages of (a) a 1.5-nm thick silicon oxynitride film oxidized without a heat treatment after the formation of an oxide film and (b) a 1.5-nm thick silicon oxynitride film oxidized after a heat treatment following the formation of an oxide film. The film thickness of each of the silicon oxynitride films (a) and (b) is a physical film thickness. As can be seen from the comparison between (a) and (b), the shift amount ΔV_{Fb} is improved by the heat treatment. This is because the number of defects in the silicon oxynitride film (b) is reduced by virtue of the heat treatment.

As described above, in accordance with this embodiment, by carrying out a heat treatment after nitridation, a silicon oxynitride film (SiON film) having the interface oxidized first can be formed. Thus, a silicon oxynitride film (SiON film) having excellent reliability can be formed. In the silicon nitride layer 8a of this silicon oxynitride film, Si—N bonds are formed, but few Si—O—H bonds exist, as mentioned in the first embodiment. Accordingly, by employing such a silicon oxynitride film of this embodiment as the tunnel insulating film of a flash memory, for example, formation of dangling bonds is restrained even when writing/erasing is repeated, and degradation of the endurance characteristics can be prevented. Also, the silicon nitride layer 8a is approximately 0.3 nm in layer thickness, and 55% to 57% in nitrogen concentration. Accordingly, the silicon nitride layer 8a is substantially made of Si₃N₄, with the first-neighbor atoms of the silicon being nitrogen atoms, and the second-neighbor atoms being silicon atoms. The nitrogen concentration of the silicon oxynitride layers 8b and 8c is 10% or lower, and are substantially silicon oxide layers (SiO₂ layers).

### Fifth Embodiment

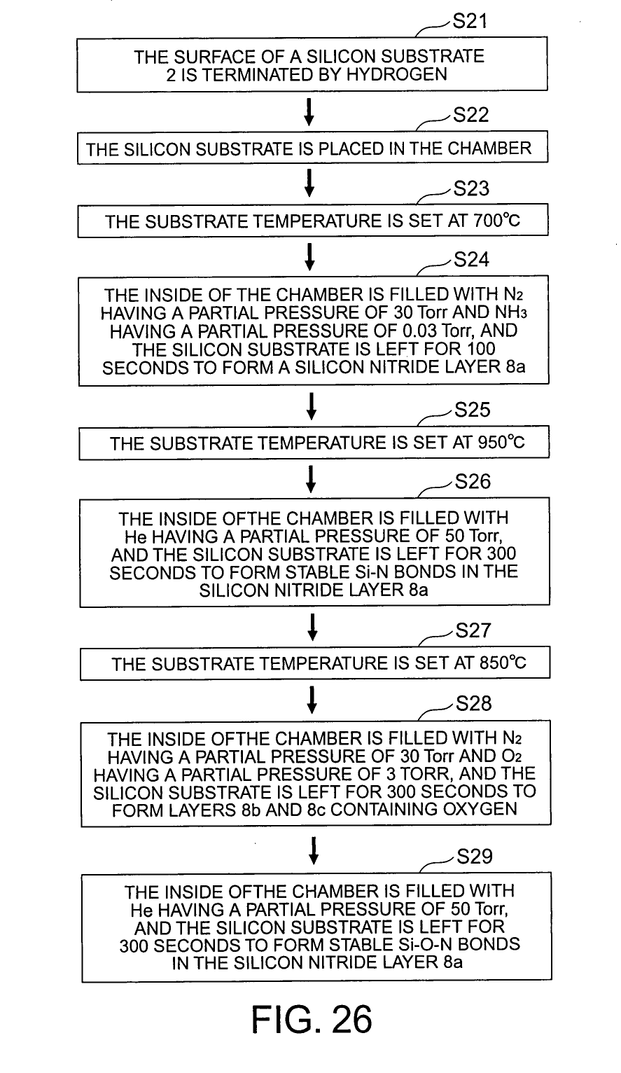

Referring now to FIG. 26, FIG. 22A, FIG. 22B, and FIG. 22C, a method for manufacturing a semiconductor memory device in accordance with a fifth embodiment of the present invention is described. The manufacturing method in accordance with this embodiment involves the same procedure as the procedure for forming the silicon oxynitride film 8 of the semiconductor memory device in accordance with the first embodiment shown in FIG. 1, except that a diluted gas is mixed with a silicon nitride film formed on the silicon substrate, and a silicon oxynitride film having a smaller fixed charge amount than a conventional silicon oxynitride film is formed. FIG. 26 is a flowchart showing the procedures in the manufacturing method in accordance with this embodiment.

First, a silicon substrate 2 is subjected to a diluted HF treatment, and the surface of the silicon substrate 2 is terminated by hydrogen (step S21, FIG. 22A). The silicon substrate 2 is then placed in a film forming chamber (step S22). The inside of the chamber is filled with a mixed atmosphere of a N₂ gas as a diluent gas with a partial pressure of 30 Torr and a NH₃ gas as a nitriding gas with a partial pressure of 0.03 Torr, and the surface of the silicon substrate 2 is heated to 700° C. and is maintained at 700° C. for 100 seconds (steps S23 and S24). By doing so, a silicon nitride layer 8a is formed on the silicon substrate 2 (FIG. 22B).

The atmosphere in the chamber is then changed to a He gas with a partial pressure of 50 Torr, for example, and the surface of the silicon substrate 2 is heated to 950° C. and is maintained at 950° C. for 300 seconds (steps S25 and S26). As a result of this, the dangling bonds in the silicon nitride layer 8a are bonded with nitrogen atoms, and stable Si—N bonds are formed in the silicon nitride layer 8a.

The inside of the chamber is then changed to a mixed atmosphere of a N₂ gas as a diluent gas with a partial pressure of 30 Torr and an O₂ gas as an oxidizing gas with a partial pressure of 3 Torr, for example, and the surface of the silicon substrate 2 is set at 850° C. and is maintained at 850° C. for 300 seconds (steps S27 and S28). By doing so, a silicon oxynitride layer 8b containing oxygen is formed between the silicon substrate 2 and the silicon nitride layer 8a, and a silicon oxynitride layer 8c containing oxygen is formed on the surface of the silicon nitride layer 8a (FIG. 22C). In this manner, a silicon oxynitride film 8 having the silicon oxynitride layer 8b, the silicon nitride layer 8a, and the silicon oxynitride layer 8c stacked in this order is formed on the silicon substrate 2.

The atmosphere in the chamber is then changed to a He gas with a partial pressure of 50 Torr, for example, and the surface of the silicon substrate 2 is heated to 950° C. and is maintained at 950° C. for 300 seconds (step S29). As a result of this, the dangling bonds in the silicon oxynitride film 8 consisting of the silicon oxynitride layer 8b, the silicon nitride layer 8a, and the silicon oxynitride layer 8c are again bonded with one another, and the number of defects in the silicon oxynitride film 8 becomes smaller.

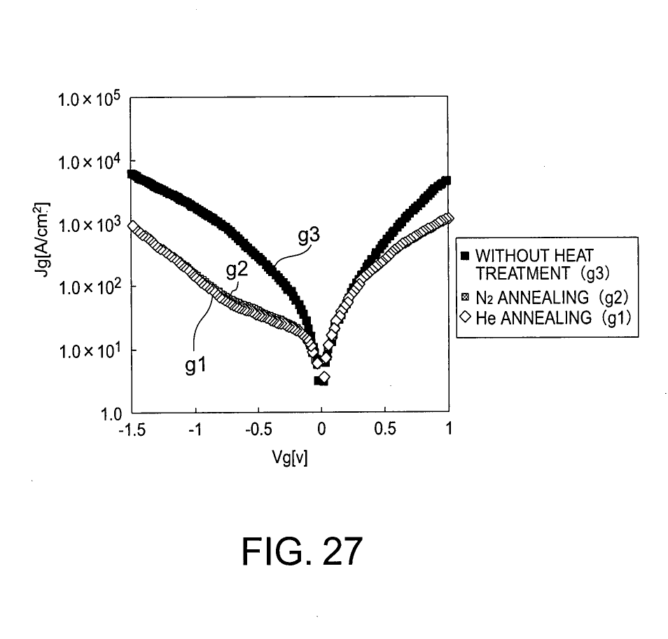

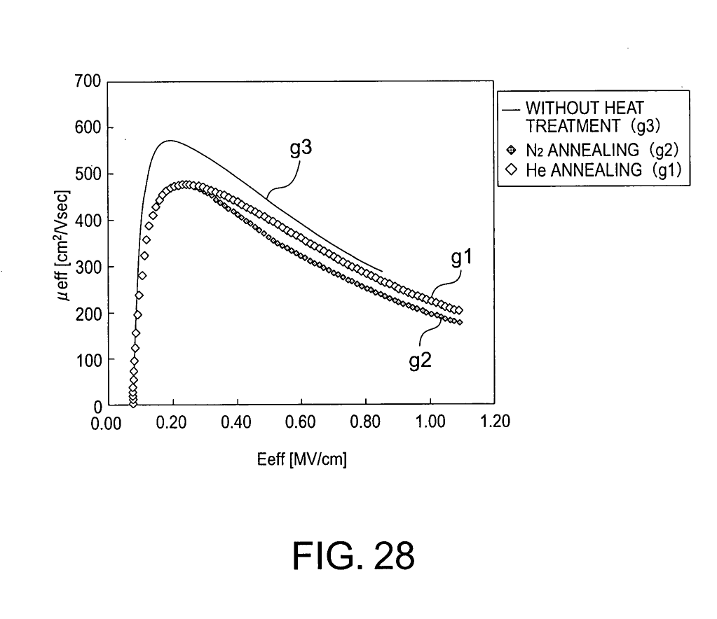

Referring now to FIGS. 27 and 28, the effects of this embodiment are described. As for the dependence of the leakage current Jg on the gate voltage Vg, FIG. 27 shows the results of comparisons of a case (graph g1) where the gate insulating film is a silicon oxynitride film subjected to a heat treatment in a helium gas atmosphere and a case (graph g2) where a gate insulating film is a silicon oxynitride film subjected to a heat treatment in a nitrogen gas atmosphere instead of helium gas, with a case (graph g3) where the gate insulating film is a silicon oxynitride film not subjected to a heat treatment. As can be seen from FIG. 27, the leakage current Jg does not vary between the case with a He gas and the case with a N₂ gas.

As for the dependence of the effective mobility μeff on the effective electric field Eeff, FIG. 28 shows the results of comparisons of the case (graph g1) where the gate insulating film is a silicon oxynitride film subjected to a heat treatment in a helium gas atmosphere and the case (graph g2) where a gate insulating film is a silicon oxynitride film subjected to a heat treatment in a nitrogen gas atmosphere instead of helium gas, with the case (graph g3) where the gate insulating film is a silicon oxynitride film not subjected to a heat treatment. The effective mobility of the electrons or holes flows in the silicon substrate just below the gate insulating film. High effective mobility indicates that the signal processing speed of the semiconductor device is high. As can be seen from FIG. 28, the gate insulating film subjected to a heat treatment in a helium gas atmosphere has a smaller decrease in effective mobility on the high electric field side than the gate insulating film subjected to a heat treatment in a nitrogen gas atmosphere.

The reason that the decrease in effective mobility is smaller in this embodiment is as follows. Since the helium reduces the atomic vibration energy in the interface between the gate insulating film and the silicon substrate due to quench effect, a reaction between the SiO₂ of the gate insulating film and the Si of the silicon substrate is restrained. Thus, the low surface roughness of the interface between the silicon substrate and the silicon oxide layer on the silicon substrate side prior to the heat treatment can be maintained after the heat treatment. In this manner, the decrease in effective mobility is restrained in this embodiment.

As described above, in accordance with this embodiment, by carrying out a heat treatment after nitridation, a silicon oxynitride film (SiON film) having the interface oxidized first can be formed. Thus, a silicon oxynitride film (SiON film) having excellent reliability can be formed. In the silicon nitride layer 8a of this silicon oxynitride film, Si—N bonds are formed, but few Si—O—H bonds exist, as mentioned in the first embodiment. Accordingly, by employing such a silicon oxynitride film of this embodiment as the tunnel insulating film of a flash memory, for example, formation of dangling bonds is restrained even when writing/erasing is repeated, and degradation of the endurance characteristics can be prevented. Also, the silicon nitride layer 8a is approximately 0.3 nm in layer thickness, and 55% to 57% in nitrogen concentration. Accordingly, the silicon nitride layer 8a is substantially made of Si₃N₄, with the first-neighbor atoms of the silicon being nitrogen atoms, and the second-neighbor atoms being silicon atoms. The nitrogen concentration of the silicon oxynitride layers 8b and 8c is 10% or lower, and are substantially silicon oxide layers (SiO₂ layers).

Also, in accordance with this embodiment, a heat treatment using a He gas is carried out after the oxidation, so as to form a SiON film having high reliability at a high speed. As in the third and fourth embodiments, it is of course possible to improve the shift amount ΔV_{Fb} of the flat-band voltage in this embodiment.

Although a N₂ gas is used as an example of a diluent gas in the second to fifth embodiments, it is possible to use some other stable gas having a similar mass to Si, such as an Ar gas.

Although a NH₃ gas is used as a nitriding gas in the second to fifth embodiments, it is possible to use some other gas capable of nitriding Si, such as nitrogen radical N* or N₂*. Although the partial pressure of the nitriding gas NH₃ is 0.03 Torr in the foregoing embodiments, it may not be 0.03 Torr, and is preferably lower than 0.03 Torr. Although the partial pressure of the diluent gas N₂ is 30 Torr in the foregoing embodiments, it may not be 30 Torr. Although the atmospheric temperature at the time of the formation of a silicon nitride layer is 700° C. in the foregoing embodiments, it may be a temperature in the range of 500° C. to 850° C. As for the atmosphere for forming a silicon nitride layer, the ratio of the partial pressure of the nitriding gas to the sum of the partial pressure of the diluent gas and the partial pressure of the nitriding gas (the dilution ratio) is preferably 5 or higher, and the total pressure is preferably 40 Torr or lower, as disclosed in Japanese Patent Application 2006-176863 relating to an invention invented by the inventors of the present invention. The dilution ratio is 5 or higher, and it is preferable to have a higher dilution ratio. However, in view of the controllability of the manufacturing devices today, the upper limit of the dilution ratio is 10000 times or lower, and a preferred upper limit is 100 times or lower, and a more preferred upper limit is 10 times or lower. The total pressure is more preferably 30 Torr or lower. It is possible to form a high-quality nitride film when the total pressure is 40 Torr or lower. It is preferable to have a lower total pressure. However, the lower limit of the total pressure should be equal to or higher than the limit of the pressure of the device in the heating process. A preferred total pressure is 1 Torr or higher, and a more preferred total pressure is 3 Torr or higher.

In the second to fifth embodiments, an O₂ gas is used as the oxidizing gas. However, it is possible to use some other gas capable of oxidizing Si, such as N₂O, NO, O*, or O₃. Although the partial pressure of the diluent gas N₂ at the time of oxidation is 30 Torr, it may not be 30 Torr. Although the atmospheric temperature at the time of oxidation is 850, it may be a temperature in the range of 800° C. to 950° C.

### Sixth Embodiment

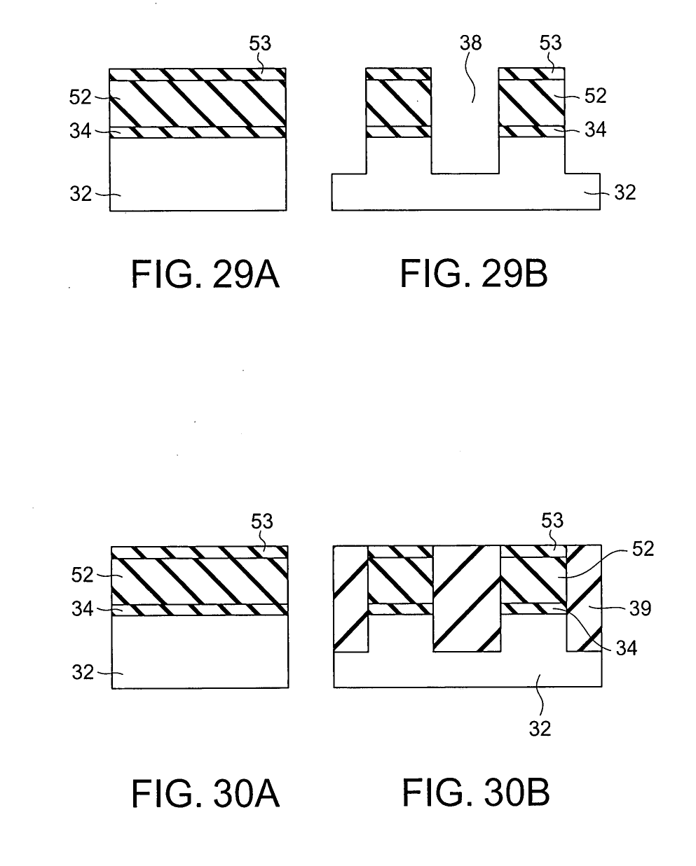

Next, a method for manufacturing a semiconductor memory device in accordance with a sixth embodiment of the present invention is described. The semiconductor memory device to be manufactured by the manufacturing method of this embodiment is a MONOS (Metal-Oxide-Nitride-Oxide-Si) nonvolatile memory that includes memory cells. Referring to FIGS. 29A to 33B, the method for manufacturing the memory of this embodiment is described. The cross section shown in each of FIGS. 29A, 30A, 31A, 32A, and 33A is perpendicular to the cross section shown in each of FIGS. 29B, 30B, 31B, 32B, and 33B.

First, by carrying out the same process as in the second embodiment, a tunnel insulating film 34 that includes a silicon oxynitride film having a stacked structure consisting of a silicon oxynitride layer, a silicon nitride layer, and a silicon oxynitride layer, and a CVD oxide film formed on the silicon oxynitride film is formed on a silicon substrate 32 (FIG. 29A). This tunnel insulating film 34 has the same structure as the tunnel insulating film 6 of the semiconductor memory device of the first embodiment, and the silicon oxynitride film of this tunnel insulating film 34 is also a nitride film with few defects.

A 6-nm thick nitride film 52 to be a charge storage layer is then deposited by CVD, and a mask material 53 to be used for device isolation is deposited by CVD. Etching is then performed on the mask material 53, the nitride film 52, and the tunnel insulating film 34 by RIE using a resist mask (not shown). Etching is further performed on the exposed regions of the silicon substrate 32, so as to form device isolating grooves 38 of 100 nm in depth, as shown in FIG. 29B.

A silicon oxide film 39 for the device isolation is deposited on the entire surface, so as to fill the device isolating grooves 38. The portions of the silicon oxide film 39 existing on the surface are removed by CMP, so as to flatten the surface. As a result, the mask material 53 is exposed (FIGS. 30A and 30B).

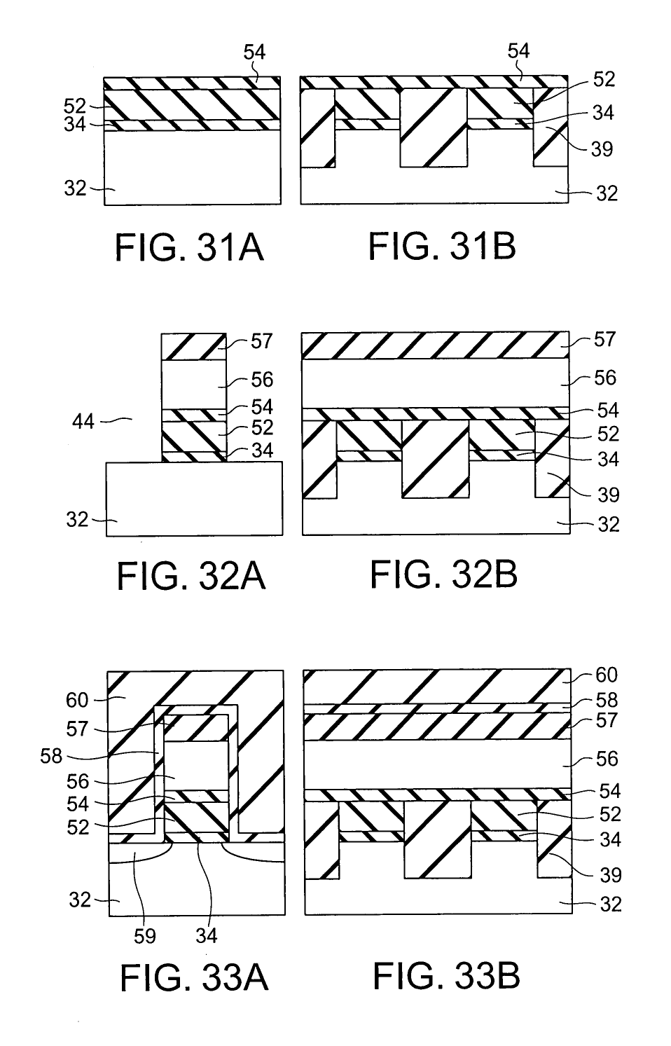

After the exposed mask material 53 is selectively removed by etching, the exposed surface of the silicon oxide film 39 is removed by etching with a diluted hydrofluoric acid solution. After that, a 15-nm thick alumina film to be an interelectrode insulating film is deposited by ALD on the entire surface. Because of the oxidizing agent used for the film formation by ALD, an extremely thin silicon oxide layer is formed in the interface between the alumina film and the nitride film 52, and a 16-nm thick interelectrode insulating film 54 having a two-layer structure consisting of an alumina film and a silicon oxide layer is formed (FIGS. 31A and 31B).

A 100-nm thick conductive layer 56 that has a two-layer structure consisting of a tungsten silicide layer and a polycrystalline silicon layer and is to be a control gate is deposited by CVD, and a RIE mask material 57 is deposited by CVD. After that, etching is performed on the mask material 57, the conductive layer 56, the interelectrode insulating film 54, the charge storage nitride film 52, and the tunnel insulating film 34 by RIE using a resist mask (not shown), so as to form slits 44 extending in the word line direction (FIGS. 32A and 32B). In this manner, the charge storage layer 52 and a control gate 56 are shaped.

Lastly, after a silicon oxide film 58 that is called an electrode sidewall oxide film is formed on the exposed face by thermal oxidation, a source/drain diffusion layer 59 is formed by ion implantation, and an interlayer insulating film 60 to cover the entire surface is formed by CVD (FIGS. 33A and 33B). After that, a wiring layer and the likes are formed by a known method, and nonvolatile memory cells are completed.

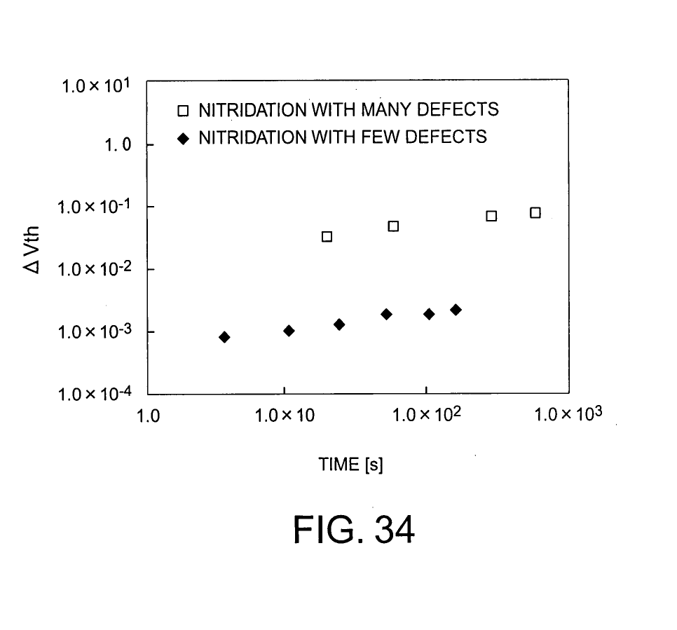

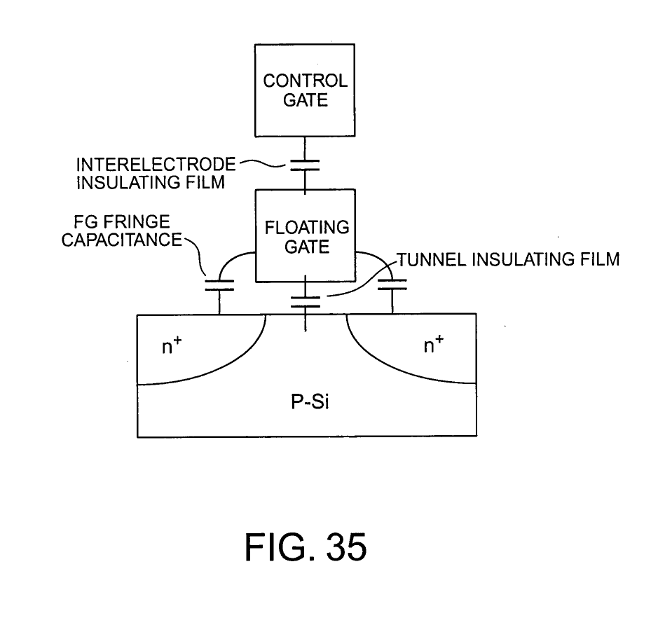

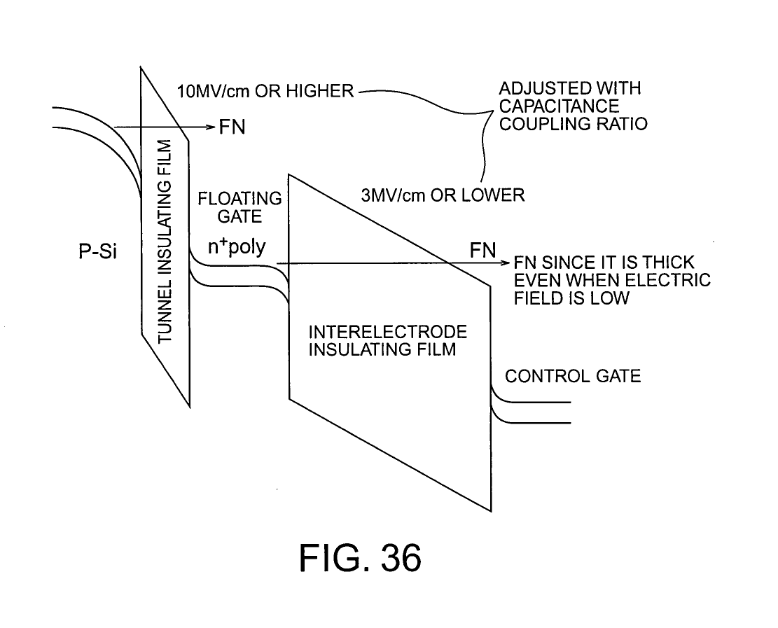

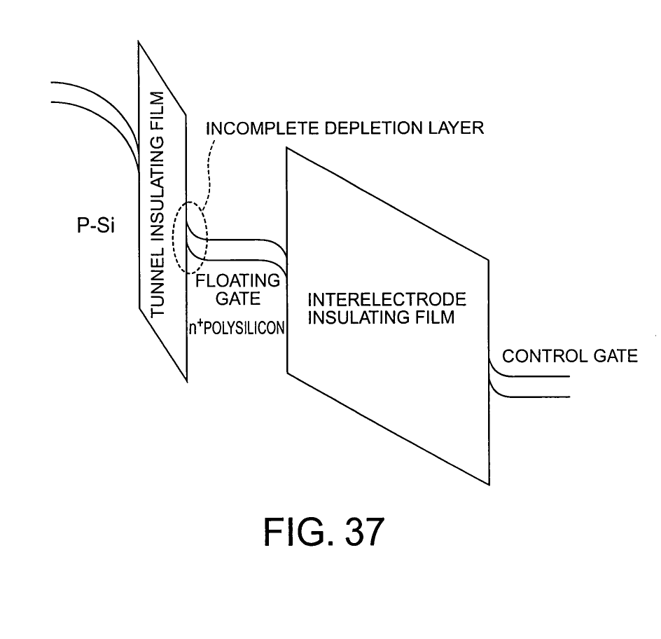

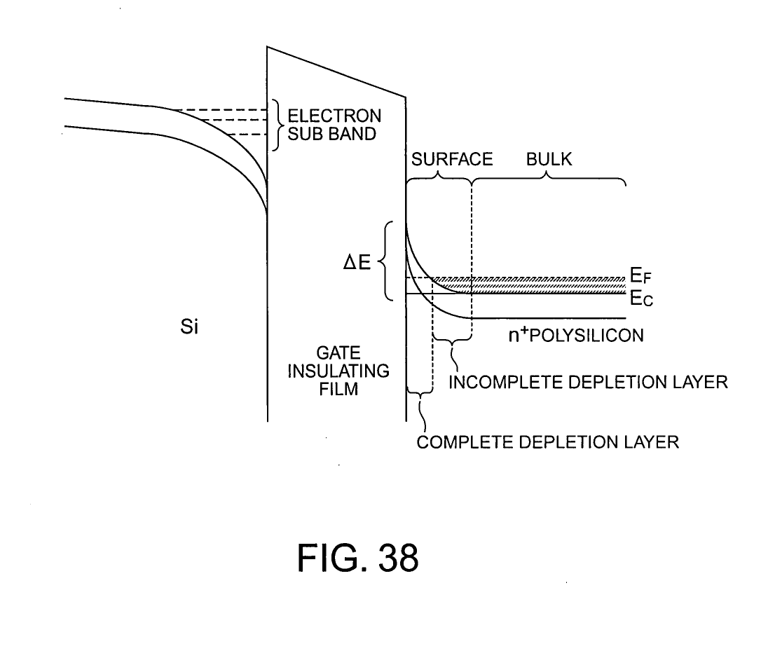

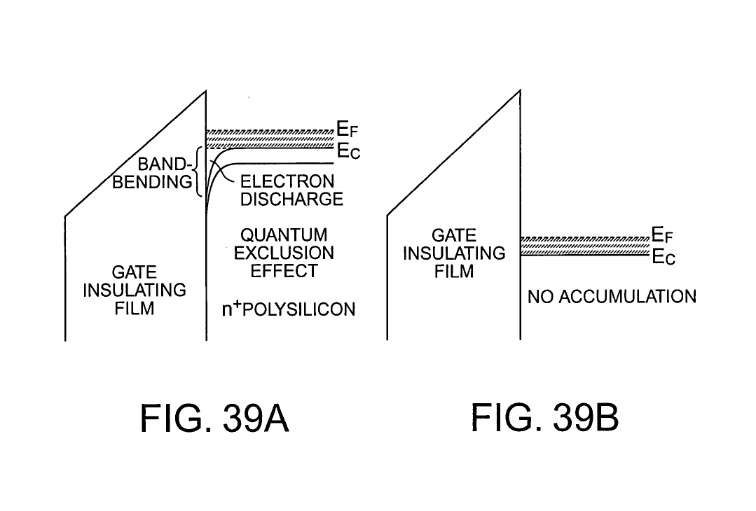

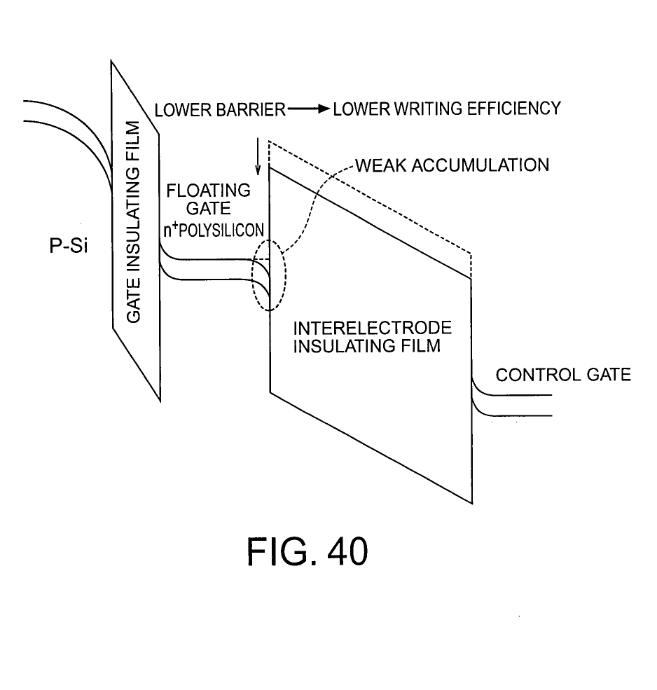

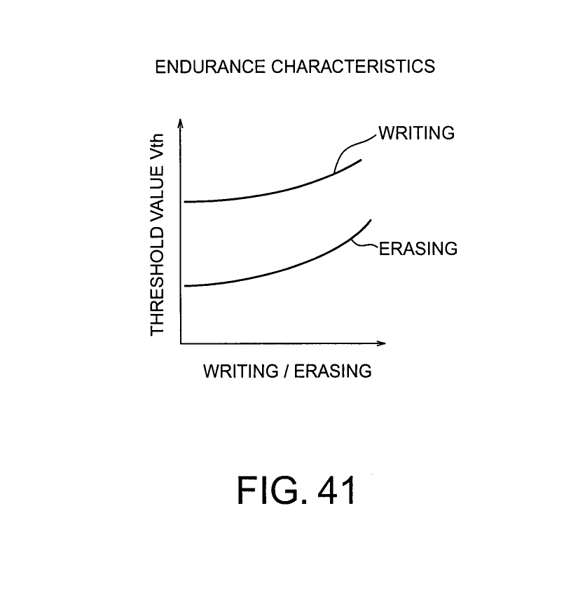

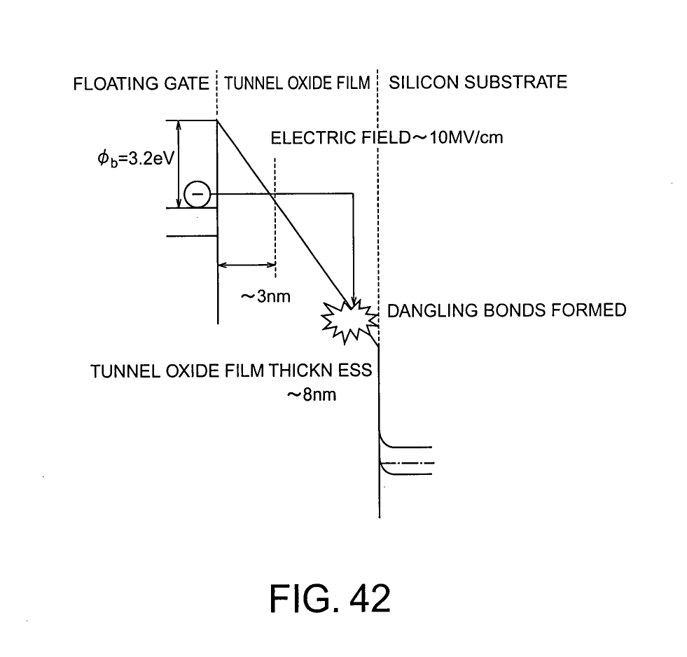

FIG. 34 shows the relationship between the stress time and the variation (ΔVth) of the threshold voltage Vth that varies with the retained charge amount, or the charge retention properties of each memory cell, which is observed where the nonvolatile memory of this embodiment has a constant voltage. As can be seen from FIG. 34, by forming a high-quality nitride film having few defects, the shift of the threshold voltage caused by a decrease in the stored charge amount is made smaller. This indicates that the charge retention properties are greatly improved. Such results are obtained because the number of leakage paths in the bulk is reduced by forming a tight network between Si and N, and the leakage current is reduced. Having a highly reliably tunnel SiON film with high nitrogen concentration, the MONOS nonvolatile memory in accordance with this embodiment can greatly improve the charge retention properties and reduce the leakage current.

The interelectrode insulating film 54 may be formed with an oxide (such as LaAlO₃) containing La and Al, which have higher permittivity, or may be formed with a high-permittivity film containing Zr or Hf.

In the memory manufactured by the manufacturing method in accordance with this embodiment, Si—N bonds are formed but few Si—O—H bonds exist in the silicon nitride layer of the silicon oxynitride film of the tunnel insulating film, as described in the first embodiment. Accordingly, even if writing or erasing is repeatedly performed, dangling bonds are not easily formed, and degradation of the endurance characteristics can be prevented. The silicon nitride layer is approximately 0.3 nm in layer thickness, and has a nitride concentration of 55% to 57% as in the first embodiment. In other words, the silicon nitride layer is substantially a Si₃N₄ layer. The first-neighbor atoms of the silicon are nitrogen atoms, and the second-neighbor atoms are silicon atoms. The nitrogen concentration in the silicon oxynitride layers 8a and 8b are restricted to 10% or lower. Accordingly, the silicon oxynitride layers are substantially silicon oxide layers (SiO₂ layers).

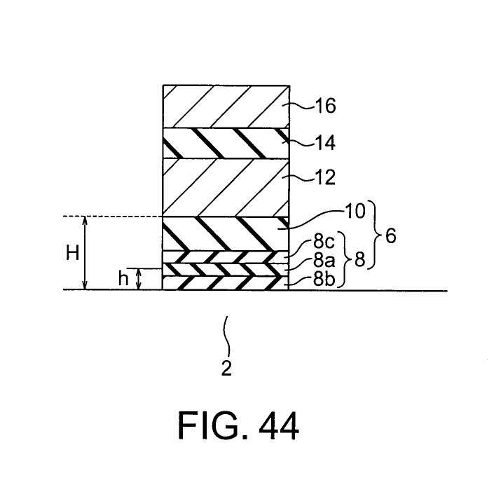

Each of the memory cells of the semiconductor memory device of the above embodiments has a source region and a drain region. However, the source region and the drain region may be removed. For example, the structure shown in FIG. 44 has the same structure as the memory cell of the semiconductor memory device of the first embodiment shown in FIG. 1, except that the source region and the drain region are eliminated.

The first common aspect among the above described embodiments is the effect of restraining generation of dangling bonds at the time of erasing, as the silicon nitride layer of the tunnel insulating film is located at approximately 1 nm from the interface with the silicon substrate. The primary reason that the Vth window as the difference between the threshold voltage Vth for writing and the threshold voltage Vth for erasing becomes narrower is the dangling bonds formed at the time of erasing, and the secondary reason is the dangling bonds formed at the time of writing.

The second common aspect is that there is not a direct correlation between the type of the interelectrode insulating film and the structure of the tunnel insulating film of each of the above embodiments, and any kinds of interelectrode insulating film may be employed. It is possible to employ any insulating film, such as an insulating film containing N, an insulating film containing Hf, an insulating film containing Zr, an insulating film containing Pr, an insulating film containing Er, or an insulating film containing Al, as long as the insulating film has compatibility with the silicon device manufacturing process.

The insulating film thicknesses mentioned in the above embodiments can be made more accurate by taking the widely known interface transition layer into consideration (see “Determination of tunnel mass and physical thickness of gate oxide including poly-Si/SiO₂ and Si/SiO₂ interfacial transition layer”, H. Watanabe, D. Matsushita, and K. Muraoka, IEEE Trans. ED vol. 53, no. 6, pp. 1323-1330, June, 2006). Also, this theory becomes truer for a thinner film such as an interface oxide layer.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concepts as defined by the appended claims and their equivalents.

What is claimed is:

1. A semiconductor memory device comprising:
a semiconductor substrate;
a first insulating film formed on the semiconductor substrate, and including a silicon oxynitride film and a silicon-rich silicon oxide film formed on the silicon oxynitride film, the silicon oxynitride film having a stacked structure formed with a first silicon oxynitride layer, a silicon nitride layer, and a second silicon oxynitride layer in order;
a charge storage layer formed on the first insulating film;
a second insulating film formed on the charge storage layer; and
a control gate that is formed on the second insulating film.

2. The device according to claim 1, wherein the charge storage layer is a floating gate made of polycrystalline silicon.

3. The device according to claim 1, wherein the charge storage layer is formed with a charge trap dielectric.

4. The device according to claim 1, wherein a film thickness of the silicon oxynitride film is 2.0 nm to 2.9 nm.

5. The device according to claim 4, wherein the silicon nitride layer is located apart from the semiconductor substrate at a distance of 0.85 nm or more.

6. The device according to claim 1, wherein a fixed charge density in the silicon oxynitride film is in a range of 2.0×10¹¹ cm⁻² to 8.0×10¹¹ cm⁻².

7. The device according to claim 1, wherein the ratio of a fixed charge density in the silicon oxynitride film to a Si—N bond density is in the range of 0.5×10⁻⁴ to 2.0×10⁻⁴.

8. The device according to claim 1, wherein the silicon nitride layer has a nitrogen concentration in a range of 55% to 57%.

9. The device according to claim 1, wherein the first and second silicon oxynitride layers have a nitrogen concentration of 10% or lower.

10. A semiconductor memory device comprising:
a semiconductor substrate;
a first insulating film formed on the semiconductor substrate, and including a silicon oxynitride film and a silicon oxide film formed on the silicon oxynitride film, the silicon oxynitride film having a stacked structure formed with a first silicon oxynitride layer, a silicon nitride layer and a second silicon oxynitride layer in order, a total film thickness of the silicon oxide film and the second silicon oxynitride layer being equal to or greater than a value obtained by dividing binding energy of silicon and hydroxyl by an electric field across the first insulating film while erasing it and an elementary electric charge;
a charge storage layer formed on the first insulating film;
a second insulating film formed on the charge storage layer; and
a control gate formed on the second insulating film.

11. The device according to claim 10, wherein the silicon nitride layer is located at a distance from an interface between the first insulating film and the charge storage layer, the distance being equivalent at least to the value obtained by dividing the binding energy of silicon and hydroxyl by the electric field across the first insulating film while erasing it and the elementary electric charge.

12. The device according to claim 10, wherein the electric field induced across the first insulating film is 10 MV/cm or more, and the binding energy of the silicon and hydroxyl in the first insulating film is 3.6 eV.

13. The device according to claim 10, wherein the charge storage layer is a floating gate made of polycrystalline silicon.

14. The device according to claim 10, wherein the charge storage layer is formed with a charge trap dielectric.

15. The device according to claim 10, wherein a film thickness of the silicon oxynitride film is 2.0 nm to 2.9 nm.

16. The device according to claim 15, wherein the silicon nitride layer is located apart from the semiconductor substrate at a distance of 0.85 nm or more.

17. The device according to claim 10, wherein a fixed charge density in the silicon oxynitride film is in the range of 2.0×10¹¹ cm⁻² to 8.0×10¹¹ cm².

18. The device according to claim 10, wherein the ratio of a fixed charge density in the silicon oxynitride film to a Si—N bond density is in the range of 0.5×10⁻⁴ to 2.0×10⁻⁴.

19. A method for manufacturing a semiconductor memory device, comprising:
placing a semiconductor substrate into a first atmosphere, thereby forming a nitride film above a surface of the semiconductor substrate, the first atmosphere containing a first nitriding gas nitriding the surface of the semiconductor substrate and a first diluent gas not substantially reacting with the semiconductor substrate during manufacture, the ratio of the sum of the partial pressure of the first diluent gas and the partial pressure of the first nitriding gas to the partial pressure of the first nitriding gas being 5 or higher, and the total pressure of the atmosphere being 40 Torr or lower;
placing the semiconductor substrate having the nitride layer formed above the surface thereof into a second atmosphere, thereby forming a first oxynitride layer between the semiconductor substrate and the nitride layer, and a second oxynitride layer on a surface of the nitride layer, the second atmosphere containing an oxidizing gas and a second diluent gas not substantially reacting with the semiconductor substrate during manufacture; and
depositing an oxide film on the second oxynitride layer by CVD, thereby forming a tunnel insulating film having a stacked structure formed with the first oxynitride layer, the nitride layer, the second oxynitride layer, and the oxide film in order.

20. The method according to claim 19, wherein the nitride layer is formed at a temperature in a range of 500° C. to 850° C.

21. The method according to claim 19, wherein the first nitriding gas contains one of NH₃, N*, and N₂*.

22. The method according to claim 19, wherein the first and second oxynitride layers are formed at a temperature in the range of 800° C. to 950° C.

23. The method according to claim 19, wherein the oxidizing gas contains one of O₂, N₂O, NO, and O₂*.

24. The method according to claim 19, further comprising:
heat-treating the semiconductor substrate having the nitride layer formed on the surface thereof in an atmosphere of a gas not substantially reacting with the semiconductor substrate, the heat-treating the semiconductor substrate being carried out between the formation of the nitride layer and the formation of the first oxynitride layer.

25. The method according to claim 24, wherein the gas not substantially reacting with the semiconductor substrate is one of a N₂ gas or a He gas.
